(19) United States
(12) Patent Application Publication
(10) Pub. No.: US 2003/0032292 A1
(43) Pub. Date: Feb. 13, 2003

(54) Fabrication method of semiconductor integrated circuit device

(75) Inventor: Junji Noguchi, Ome (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 10/198,143

(22) Filed: Jul. 19, 2002

(30) Foreign Application Priority Data
Aug. 7, 2001 (JP) 2001-238945

(51) Int. Cl. H01L 21/302; H01L 21/461

(52) U.S. Cl. 438/692; 438/690

(57) ABSTRACT

Provided is a fabrication method of a semiconductor integrated circuit device having a post-CMP cleaning apparatus equipped with at least two drying chambers downstream of a cleaning chamber. This makes it possible to dry wafers in parallel, thereby improving the through-put of the post-CMP cleaning.

### BACKGROUND OF THE INVENTION

The present invention relates to a fabrication method of a semiconductor integrated circuit device, particularly to a technique effective when applied to formation of inlaid interconnects by chemical mechanical polishing (CMP).

Post-CMP cleaning apparatuses investigated by the present inventors have two cleaning chambers, that is, first and second brush cleaning chambers and one drying chamber disposed downstream of the brush cleaning chambers. Wafers after CMP are cleaned successively in the first and second brush cleaning chambers, and then transferred to the drying chamber where they are dried.

Disclosed, for example, in Japanese Patent Laid-Open No. Hei 7(1995)-135192 is a technique of carrying out, without drying of wafers, a series of steps comprising polishing, physical cleaning, cleaning with a chemical solution and rinsing in order to reduce particles left after chemical mechanical polishing. During this series of cleaning steps, one drying chamber is disposed. Disclosed, for example, in Japanese Patent Laid-Open No. 2001-35821 is a CMP technique which comprises a cleaning step simplified by disposing a plurality of cleaning apparatuses different in cleaning manners. Disclosed, for example, in Japanese Patent No. 2001-62411 is a technique of disposing three cleaning apparatuses and dryers per CMP apparatus. Disclosed, for example, in Japanese Patent Laid-Open No. Hei 11(1999)-251275 is a technique of cleaning wafers by bringing them in contact with warm pure water or steam. Disclosed, for example, in Japanese Patent Laid-Open No. 2000-332080, is a technique of shortening treating time by carrying out treatment under fixed conditions in a treatment section. Disclosed, for example, in Japanese Patent Laid-Open No. Hei 11(1999)-16912 is a technique of forming, in an insulating film, a hole from which an inlaid interconnect made of copper is to be exposed, and changing the oxidized portion at the bottom of the hole into copper by subjecting it to heat treatment, plasma treatment or ultraviolet exposure under a reducing atmosphere of hydrogen or ammonia.

### SUMMARY OF THE INVENTION

The present inventors have however found that the above-described post-CMP cleaning techniques are accompanied with the below-described problems.

The first problem is that a treating rate in a post-CMP cleaning apparatus is controlled by drying time, which disturbs improvement in throughput. The cleaning time in the first and second brush cleaning chambers of the post-CMP cleaning apparatus investigated by the present inventors is, for example, about 10 to 30 seconds, while about 20 to 60 seconds is necessary for drying in the drying chamber. Accordingly, the throughput of the post-CMP cleaning is limited by the drying time. The present inventors have revealed for the first time that when wafers are brush-cleaned for long hours, the dished shape of an inlaid interconnect (particularly, isolated inlaid interconnect) made of copper becomes marked owing to the friction with the brush or influence of a cleaning solution, leading to abnormalities of interconnect resistance or interconnect shape. It has also been revealed for the first time by the present inventors that this problem becomes more eminent by so-called abrasive-free polishing that is, polishing without using an abrasive (or with a reduced amount of an abrasive). FIG. 58 shows the relationship between the generation (and interconnect pitch) of CMOS (Complementary MOS) having an inlaid interconnect structure made of copper (Cu) and an interconnect resistance (and interconnect resistance increasing ratio). This relationship is made on the supposition that the polished amount of the inlaid interconnect is fixed at about 50 nm. The graph shows that actual interconnect resistance (at a polished amount of 50 nm) becomes at least 2 times as much as that of the ideal interconnect resistance (at a polished amount of 0 nm) in the 0.06 μm generation. The total dished amount aimed in the next 0.09 μm generation is about 30 nm. Without some countermeasures against not only the removal of an inlaid interconnect which occurs during CMP but also removal of an inlaid interconnect which occurs during post-CMP cleaning, this excessive dished amount will be a serious problem in the next generation process.

An object of the present invention is to provide a technique capable of improving the throughput of post-CMP cleaning.

The above-described and other objects and novel features of the invention will be apparent from the description herein and accompanying drawings.

Typical embodiments of the invention are briefly described below.

In the present invention, there is thus provided a fabrication method of a semiconductor integrated circuit device which comprise, upon post-CMP cleaning, cleaning wafers and then drying them in a plurality of drying chambers in parallel.

### BRIEF DESCRIPTION OF THE DRAWINGS

FIG. 1 is a plain view illustrating a sample used in TDDB life measurement in the present invention;

FIG. 2 is a cross-sectional view taken along a line B-B′ in FIG. 1;

FIG. 3 is a cross-sectional view taken along a line C-C′ in FIG. 1;

FIG. 4 is a concept view showing the outline of measurement;

FIG. 5 is one example of current-voltage measurement result;

FIG. 6 is an explanatory view of one example of a post-CMP cleaning apparatus according to Embodiment 1 of the invention;

FIG. 7 is an explanatory view of one example of a CMP apparatus according to Embodiment 2 of the invention;

FIG. 8 is an explanatory view of a polishing section of the CMP apparatus in FIG. 7;

FIG. 9 is an explanatory view of a cleaning apparatus of the CMP apparatus in FIG. 7;

FIG. 10 is an enlarged perspective view of a brush used in the cleaning apparatus of FIG. 9;

FIG. 11 is an explanatory view of one example of a disk type cleaning system;

FIG. 12 is a fragmentary cross-sectional view of FIG. 11:

FIG. 13 is an explanatory view of one example of a pen type cleaning system;

FIG. 14 is a cross-sectional view of FIG. 13;

FIG. 15 is a cross-sectional view of one example of a plasma treating apparatus;

FIG. 16 is a plain view of one example of the plasma treating apparatus of FIG. 15;

FIG. 17 is a flowchart showing a fabrication method of a semiconductor integrated circuit device according to Embodiment 2 of the invention;

FIG. 18 is a fragmentary plain view of a semiconductor integrated circuit device of FIG. 17 during fabrication;

FIG. 19 is a cross-sectional view taken along a line X1-X1 in FIG. 18;

FIG. 20 is a fragmentary plan view of wafer 2 during fabrication step following FIGS. 18 and 19;

FIG. 21 is a cross-sectional view taken along a line X2-X2 in FIG. 20;

FIG. 22 is a fragmentary cross-sectional view of a semiconductor integrated circuit device during a fabrication step following FIGS. 21 and 22;

FIG. 23 is a fragmentary cross-sectional view of a semiconductor integrated circuit device during a fabrication step following FIG. 22;

FIG. 24 is a fragmentary cross-sectional view of a semiconductor integrated circuit device during a fabrication step following FIG. 23;

FIG. 25 is a fragmentary cross-sectional view of a semiconductor integrated circuit device during a fabrication step following FIG. 24;

FIG. 26 is a fragmentary cross-sectional view of a semiconductor integrated circuit device during a fabrication step following FIG. 25;

FIG. 27 is a graph showing the relationship between electric field intensity and TDDB life;

FIG. 28 is a fragmentary cross-sectional view of one example of CMIS-LSI;

FIG. 29 is a fragmentary cross-sectional view of a semiconductor integrated circuit device according to Embodiment 3 of the invention during fabrication;

FIG. 30 is a graph illustrating the relationship between electric field intensity and TDDB life;

FIG. 31 is a graph illustrating dependence of interconnect resistance on hydrogen anneal;

FIG. 32 is a fragmentary cross-sectional view of a semiconductor integrated circuit device according to Embodiment 4 of the invention during fabrication;

FIG. 33 is an enlarged fragmentary plain view of FIG. 32:

FIG. 34 is a fragmentary cross-sectional view of FIG. 33;

FIG. 35 is a fragmentary cross-sectional view of a semiconductor integrated circuit device during a fabrication step following FIGS. 32 to 34;

FIG. 36 is a fragmentary enlarged plain view of FIG. 35;

FIG. 37 is a fragmentary plain view of FIG. 36:

FIG. 38 is a fragmentary cross-sectional view of a semiconductor integrated circuit device during a fabrication step following FIG. 37;

FIG. 39 is a fragmentary cross-sectional view of FIG. 38;

FIG. 40 is a fragmentary cross-sectional view of FIG. 39;

FIG. 41 is a flow chart of the fabrication method of a semiconductor integrated circuit device according to Embodiment 4 of the invention;

FIG. 42 is a graph illustrating the TDDB life;

FIG. 43 is a graph illustrating the TDDB life in Embodiment 5;

FIG. 44 is a fragmentary cross-sectional view of a semiconductor integrated circuit device according to Embodiment 6 of the invention during fabrication;

FIG. 45 is a plain view of the semiconductor integrated circuit device during a fabrication step following FIG. 44;

FIG. 46 is a cross-sectional view taken along a line X3-X3 of FIG. 45;

FIG. 47 is a cross-sectional view of the semiconductor integrated circuit device during a fabrication step following the step of FIGS. 45 and 46;

FIG. 48 is a fragmentary plain view of the semiconductor integrated circuit device according to Embodiment 7 of the invention during fabrication;

FIG. 49 is a cross-sectional view taken along a line X4-X4 in FIG. 48;

FIG. 50 is a fragmentary plain view of the semiconductor integrated circuit device during a fabrication step following the step of FIGS. 48 and 49;

FIG. 51 is a cross-sectional view taken along a line X5-X5 in FIG. 50;

FIG. 52 is a fragmentary plain view of the semiconductor integrated circuit device during a fabrication step following the step of FIGS. 50 to 51;

FIG. 53 is a cross-sectional view taken along a line X6-X6 in FIG. 52;

FIG. 54 is a fragmentary plain view of the semiconductor integrated circuit device during a fabrication step following the step of FIGS. 52 and 53;

FIG. 55 is a cross-sectional view taken along a line X7-X7 in FIG. 54;

FIG. 56 is a fragmentary plain view of the semiconductor integrated circuit device during a fabrication step following the step of FIGS. 54 and 55;

FIG. 57 is a cross-sectional view taken along a line X8-X8 in FIG. 55; and

FIG. 58 is a graph illustrating the relationship between the generation (and interconnect pitch) of CMOS having an inlaid interconnect structure made of copper and interconnect resistance (and interconnect resistance increasing ratio).

### DETAILED DESCRIPTION OF THE PREFERRED EMBODIMENTS

Prior to detailed description of the invention, meanings of the terms used in the invention will next be explained.

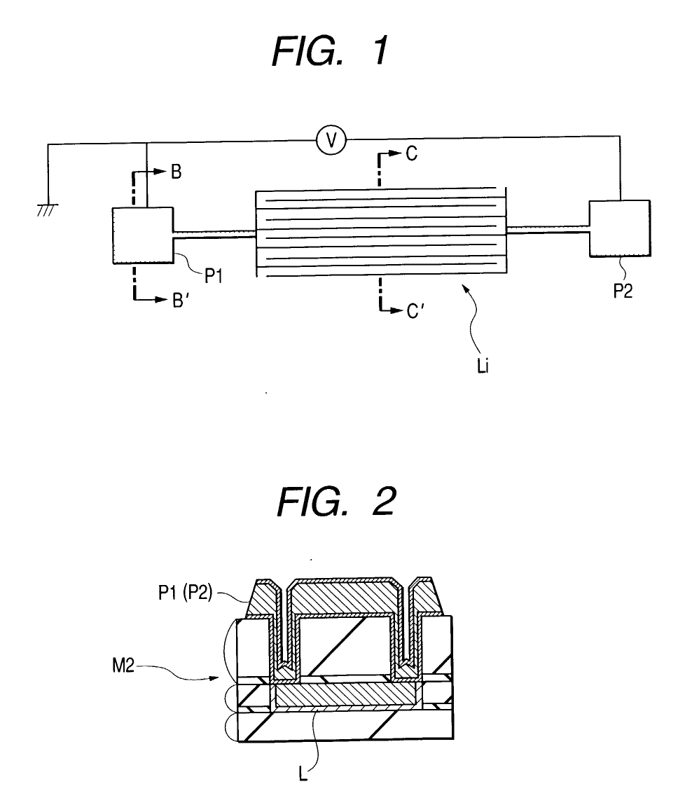

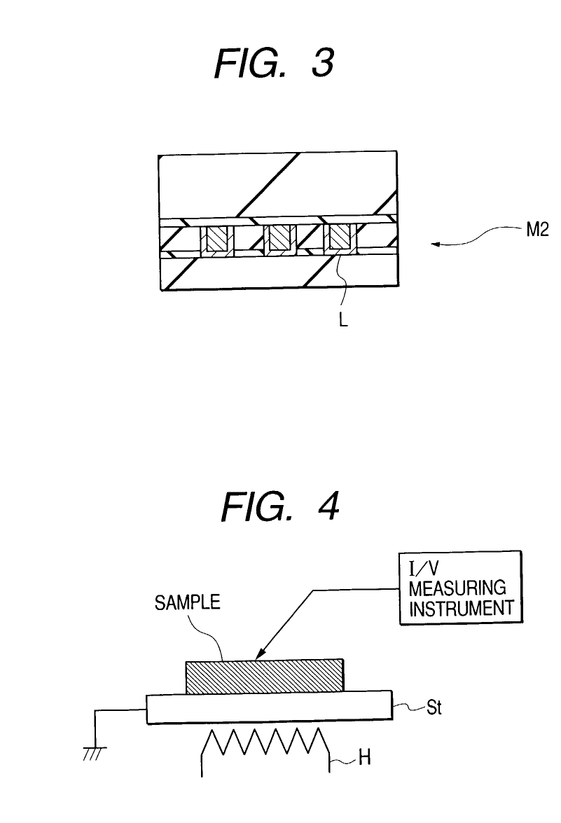

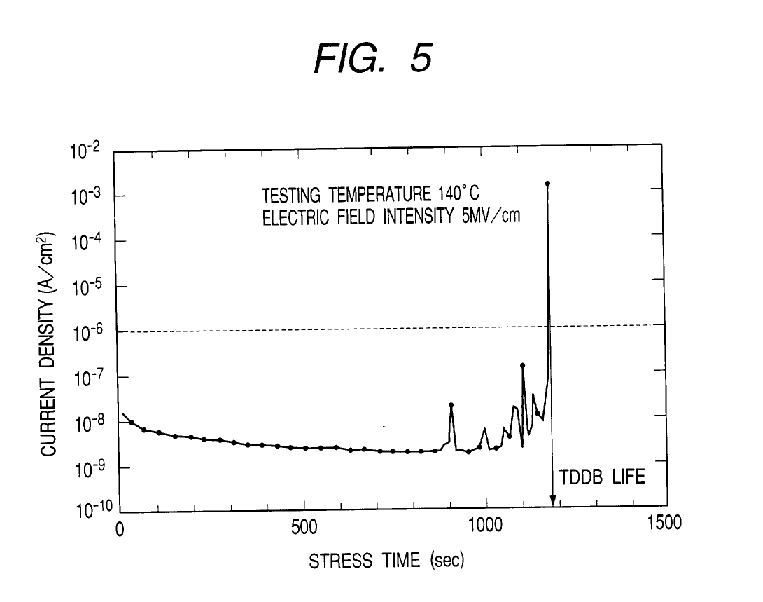

1. TDDB (Time Dependence on Dielectric Breakdown) life is a time (life) determined by applying a comparatively high voltage between electrodes under a measuring condition of a predetermined temperature (e.g. 140° C.), plotting a graph of time from voltage application up to dielectric breakdown against an applied electric field, and extrapolating an actually used electric field intensity (e.g. 0.2 MV/cm) in the graph. FIG. 1 is a plain view illustrating a sample used in measurement of the TDDB life in the present invention; and FIGS. 2 and 3 are cross-sectional views taken along lines B-B′ and C-C′ in FIG. 1, respectively. The sample can be formed in a TEG (Test Equipment Group) region on a semiconductor wafer (hereinafter called “wafer” simply). As shown in the diagram, a pair of comb-shaped interconnects L are formed in a second interconnect layer M2 and connected respectively to the pads P1, P2 of the upper most layer. When an electric field is applied between these comb-shaped interconnects L engaged each other, a leak current between the comb-shaped interconnects Li is measured. The pads P1, P2 are measuring terminals. The width, distance and thickness of the comb-shaped interconnects L are each 0.5 μm. The length of the interconnects opposite to each other was set at 1.58×10^{5 μ}m. FIG. 4 is a concept view showing the outline of measurement. The sample is held on a measuring stage St, and a current-voltage measuring instrument (I/V measuring instrument) is connected between the pads P1, P2. The measuring stage St is heated by a heater H, whereby a sample temperature is adjusted to 140° C. FIG. 5 illustrates one example of a current-voltage measurement result. Measurement was conducted under the conditions of a sample temperature 140° C. and an electric field intensity of 5 MV/cm. Of two methods for measuring the TDDB life, that is, a constant-voltage stress method and a low-current stress method, the former one wherein an average electric field applied to an insulating film is constant is employed in this embodiment. After voltage application, a current density decreases with time, and thereafter a drastic current increase (dielectric breakdown) is observed. Here, time necessary for the leak current density to reach 1 μmA/cm² is taken as a TDDB life (TDDB life at 5 Mv/cm). In this embodiment, the term “TDDB life” means a breakdown time (life) at 0.2 MV/cm unless otherwise specified, however, it may be used in a broad sense as a time until breakdown if a predetermined field intensity is specified. Unless otherwise specified, TDDB life refers to the case where the sample temperature is 140° C. Although the term “TDDB life” means the life measured using the comb-shaped interconnect Li, but needless to say, it reflects the breakdown life between actual interconnects.

2. The term “plasma treatment” means a treatment of exposing the surface of a substrate to an environment under plasma state or, if a member such as an insulating film or a metal film is formed over the substrate, exposing the surface of the member to such an environment, thereby subjecting the surface to the chemical and mechanical (bombardment) actions of the plasma. Plasma is usually generated by, while filling a reaction chamber purged with a specific gas (treatment gas) with the treatment gas as needed, ionizing the gas by the action of a high frequency field. It is however impossible to completely purge the chamber with the treatment gas. In this embodiment, therefore, the term “ammonia plasma” does not means a complete ammonia plasma but it may contain impurity gases (such as nitrogen, oxygen, carbon dioxide and vapor). Similarly, it is needless to say that the plasma may contain another dilution gas or additive gas.

The term “plasma of a reducing atmosphere” means a plasma environment wherein reactive species such as radicals, ions, atoms and molecules which have a reducing action, that is, an oxygen withdrawing action, exist dominantly. These radicals or ions include atomic or molecular radicals or ions. Moreover, the environment may contain not only a single reactive species but plural reactive species. For example, the environment may having therein hydrogen radicals and NH₂ radicals simultaneously.

3. In this embodiment, the term “made of copper” means “composed mainly of copper”. Even high-purity copper always contain impurities. Even if a member made of copper contains an additive or an impurity, it is not excluded. In this embodiment, the term “made of high-purity copper” means “made of copper as pure as an ordinarily used high-purity material (for example, 4N (99.99%)) or higher and is premised to contain an arbitrary impurity in an amount of about 0.01%. This does not only apply to copper but also applies to another metal (such as titanium nitride).

4. The term “chemical mechanical polishing” (CMP) means polishing of a polish surface by relatively moving it in the direction of the surface while supplying a slurry in a state where the polish surface is brought in contact with a polishing pad formed of a sheet material such as a soft cloth. In this embodiment, this term also embraces CML (chemical mechanical lapping) for polishing the polish surface by moving it relative to the surface of a hard grindstone, polishing with another fixed abrasive, and abrasive-free CMP.

5. The term “abrasive-free chemical mechanical polishing” usually means chemical mechanical polishing using a slurry having an abrasive weight concentration less than 0.5 wt. %, while the term “abrasive-used chemical mechanical polishing” means chemical mechanical polishing using a slurry having an abrasive weight concentration of 0.5 wt. % or greater. However, these definitions are relative. When abrasive-free chemical mechanical polishing is employed as a first step polishing, followed by abrasive-used chemical mechanical polishing as a second step polishing, and the polishing concentration of the first step is smaller by at least single digit, preferably at least double digits than that of the second step, polishing of this first step may be called “abrasive-free chemical mechanical polishing”. The term “abrasive-free chemical mechanical polishing” in this embodiment embraces, as well as a case wherein the whole unit planarization process of a metal film is conducted by abrasive-free chemical mechanical polishing, a case wherein abrasive-free chemical mechanical polishing is applied to a main process, but abrasive-used chemical mechanical polishing is applied to a secondary process. The term “abrasive-free CMP” may qualitatively means the whole CMP with a slurry containing an oxidizing agent of copper, an anticorrosive of copper and an etchant of copper oxide.

6. The term “polishing solution (slurry)” usually means a suspension obtained by mixing a chemical etchant with a polishing abrasive. In this embodiment, owing to the nature of the invention, however, it embraces a suspension wherein no polishing abrasive has been mixed.

7. The term “abrasive (slurry particles)” usually means a powder, such as alumina and silica, contained in the slurry.

8. The term “anticorrosive” means a chemical which forms, on the surface of a metal, a protective film having either or both of anticorrosive and hydrophobic properties, thereby stopping or suppressing the progress of polishing by CMP. As the chemical, benzotriazole (BTA) is generally used (for detail, see Japanese Patent Laid-Open No. Hei 8(1996)-64594).

9. The term “conductive barrier film” usually means a conductive film having a diffusion barrier property formed comparatively thin on a side surface or bottom of an inlaid interconnect in order to prevent copper from diffusing into an interlayer insulating film or underlying layer. A refractory metal or nitride thereof, such as titanium nitride (TiN), tantalum (Ta) or tantalum nitride (TaN) is ordinarily employed for the conductive barrier film.

10. The term “inlaid interconnect” or “inlaid metal interconnect” usually means an interconnect patterned by a metallization technique of removing, from a conductive film embedded inside of a trench or hole formed in the insulating film, an unnecessary portion on the insulating film, as in single damascene or dual damascene. The term “single damascene” usually means an inlaid interconnect forming process wherein a plug metal and a interconnect metal are embedded in two stages. The term “dual damascene” usually means an inlaid interconnect forming process wherein a plug metal and an interconnect metal are embedded simultaneously. Copper inlaid interconnects tend to be used as a multi-level structure.

11. The term “selective removal”, “selective polishing”, “selective etching” or “selective chemical mechanical polishing” means removal, polishing, etching or chemical mechanical conducted at a selectivity of 1 or greater, for example, 5 or greater.

12. The term “semiconductor integrated circuit device” as used herein means not only a device fabricated on a single-crystal silicon substrate but also a device fabricated on another substrate such as SOI (silicon on insulator) substrate or TFT (thin film transistor) liquid crystal manufacturing substrate unless otherwise specified.

13. The term “wafer” means a single-crystal silicon substrate (generally in a substantially disk form), an SOS (silicon on sapphire) substrate, a glass substrate, other insulating, semi-insulating or semiconductor substrates or a composite substrate thereof, each used for manufacturing a semiconductor integrated circuit device. It also embraces a substrate, a part or whole of the substrate surface or a part or whole of the gate electrode has been made of another semiconductor such as SiGe.

14. The term “semiconductor integrated circuit chip (semiconductor integrated circuit substrate)” or “semiconductor chip (semiconductor substrate)” means a wafer divided into unit-circuit groups after completion of a wafering step.

15. The term “silicon nitride” or “silicon nitride film” means not only Si₃N₄ or an insulating film thereof but also a nitride of silicon having a similar composition to Si₃N₄ or an insulating film thereof.

16. The “wafer process” is also called a preliminary process. This term means a process of from a mirror-polished wafer (mirror wafer) state through formation steps of elements and interconnects, and then a surface protective film to a state that electrical tests with a probe can be conducted.

17. The term “low-dielectric-constant insulating film” or “insulating material” means as an insulating film having a dielectric constant lower than that of a silicon oxide film (e.g. TEOS (tetraethoxysilane) oxide film) included in a protective film formed as a passivation film. Usually, it means a film having a dielectric constant E lower than that of TEOS oxide film, that is, about 4.1 or 4.2.

In the below embodiments, explanations will be made after divided into a plurality of sections or embodiments. It is however noted that, unless otherwise specifically indicated, they are not independent each other but in a relationship that one is a modification, detail, supplementary explanation to a part or the entire of another.

Also, in the below-described embodiments of the invention, where reference is made to the number of elements (including number, numerical value, amount and range), it is not limited to the particular number but may be greater or smaller than it, unless otherwise particularly indicated or clearly limited to a particular number on the principle.

Similarly, when reference is made to the shape or positional relationship of constituting elements, those substantially close or similar to their shapes or the like are included unless otherwise specifically indicated or presumed to be apparently different in principle. This also applies to the above-described numerical value and range.

Incidentally, in all the drawings for illustrating embodiments of the invention, elements having like function will be identified by like reference numerals and overlapping descriptions will be omitted.

In the drawings used in the embodiments of the invention, a plain view may be hatched to facilitate the observation.

In the embodiments of the invention, MISFET (metal insulator semiconductor field effect transistor) representative of a field-effect transistor is abbreviated as MIS, a p-channel MISFET is abbreviated as pMIS, and an n-channel MISFET is abbreviated as as nMIS.

The embodiments of the invention will next be described in detail based on accompanying drawings.

(Embodiment 1)

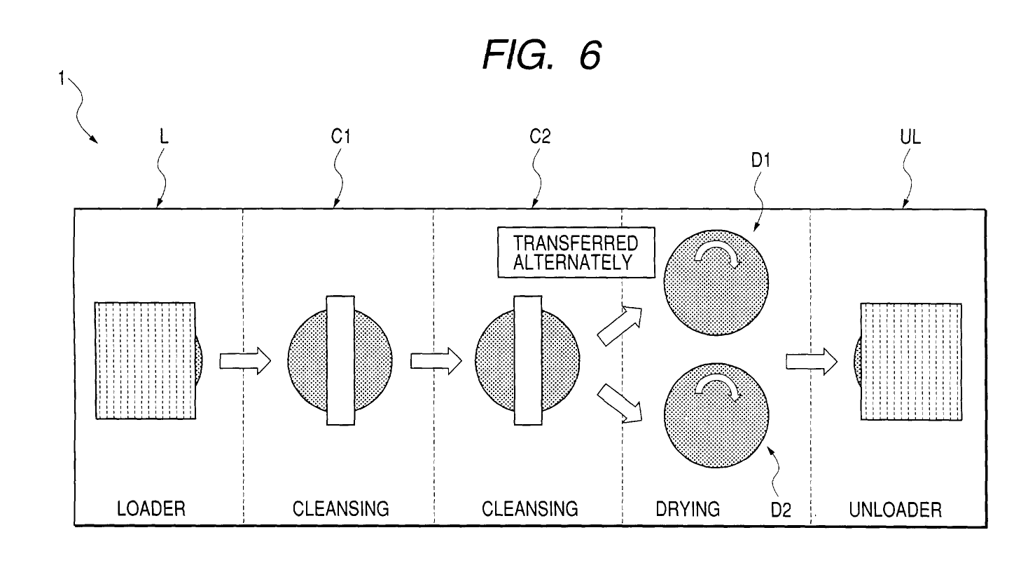

FIG. 6 illustrates a post-CMP cleaning apparatus 1 of this Embodiment 1. This post-CMP cleaning apparatus 1 is a single-wafer cleaning and drying apparatus for successively cleaning and drying a wafer 2 after CMP treatment. It has a loader L, a brush cleaning chamber C1 disposed downstream thereof, a brush cleaning chamber C2 disposed downstream thereof, two drying chambers D1,D2 disposed downstream thereof in parallel, and an unloader UL disposed downstream thereof. Between the loader L and brush cleaning chamber C1, there may be interposed an ultrasonic cleaning chamber such as so-called megasonic cleaning chamber which irradiates ultrasonic waves of a megahertz frequency in a liquid. Adoption of megahertz frequency makes it possible to increase the threshold value of cavitation, remove fine particles and moreover, decrease generation of damages. Upon transfer of CMP treatment to cleaning, the surface of the wafer 2 must be wet during the period from water cleaning rightly after CMP treatment until the wafer is carried in the brush cleaning chamber 1b1.

The loader L is a part for carrying the CMP-treated wafer 2 into the post-CMP cleaning apparatus 1. This loader L may be equipped with a mechanical unit for dipping the wafer 2 in pure water or a mechanical unit for spraying pure water to the wafer 2, thereby keeping the surface of the wafer 2 wet. In this loader L, timing to carry the wafer 2 in the brush cleaning chambers C1,C2 and drying chambers D1,D2 is adjusted. This means that the wafer 2 is transferred from the loader L to the drying chambers D1,D2 smoothly without waiting. The unloader UL is a mechanical unit for carrying the cleaned and dried wafer 2 outside of the post-CMP cleaning apparatus 1.

The brush cleaning chamber C1 is a cleaning chamber mainly for removing a slurry, for example, by alkali cleaning. This chamber has a structure permitting brush cleaning for 10 seconds with a chemical solution containing about 0.1% of NH₄OH and for 10 seconds with pure water, 20 seconds in total. The brush cleaning chamber C2 is a cleaning chamber mainly for removing heavy metals, for example, by acid cleaning. This chamber has a structure permitting brush cleaning for 10 seconds with a chemical solution containing about 0.1% of HF and for 10 seconds with pure water, 20 seconds in total. The cleaning time (total cleaning time in the brush cleaning chambers C1 and C2) is set equal to or shorter than the drying time in the drying chambers D1,D2. In particular, the cleaning time in each of the brush cleaning chambers C1,C2 with brush and chemical solution is set shorter than the drying time in the drying chambers D1,D2.

The drying chambers D1,D2 are chambers for drying the wafer 2 after cleaning. Drying is carried out, for example, by spin drying or lamp annealing. The drying time of the post-CMP cleaning apparatus 1 is set, for example, at about 40 seconds. In this embodiment, however, the effective drying time can be reduced to 20 seconds because one post-CMP cleaning device is equipped with two drying chambers D1,D2. Disposal of two drying chambers D1,D2 in this Embodiment as described above makes it possible to improve the through-put of the post-CMP cleaning because of the following two reasons. One is that brush cleaning can be conducted without being disturbed by the progress of drying treatment, whereby latency time in the brush cleaning step can be eliminated. The other one is that two wafers 2 can be dried by one drying treatment.

According to this Embodiment, an increase in the interconnect resistance of an inlaid interconnect made of copper can be suppressed or prevented because of the following reasons. For example in a post-CMP cleaning process which needs 20 seconds cleaning and 40 seconds drying, a brush-cleaned wafer must wait for about 20 seconds until dying starts when the apparatus is equipped with only one drying chamber. The wafer waiting under such a state presumably becomes dry or corroded so that excessive cleaning must be continued for further 20 seconds. As described above, owing to mechanical action by a brush or chemical action of a chemical solution during CMP or during cleaning inevitably removes the upper layer of the inlaid interconnect, leading to a marked increase in the interconnect resistance. Particularly in the interconnects which are isolated each other, removal by a chemical solution tends to occur. According to this Embodiment, however, excessive cleaning which will otherwise be conducted during the latency time in brush cleaning becomes unnecessary, making it possible to suppress or prevent the inlaid interconnect made of copper from being removed during brush cleaning. Accordingly, an increase of the interconnect resistance of an inlaid interconnect made of copper can be suppressed or prevented.

(Embodiment 2)

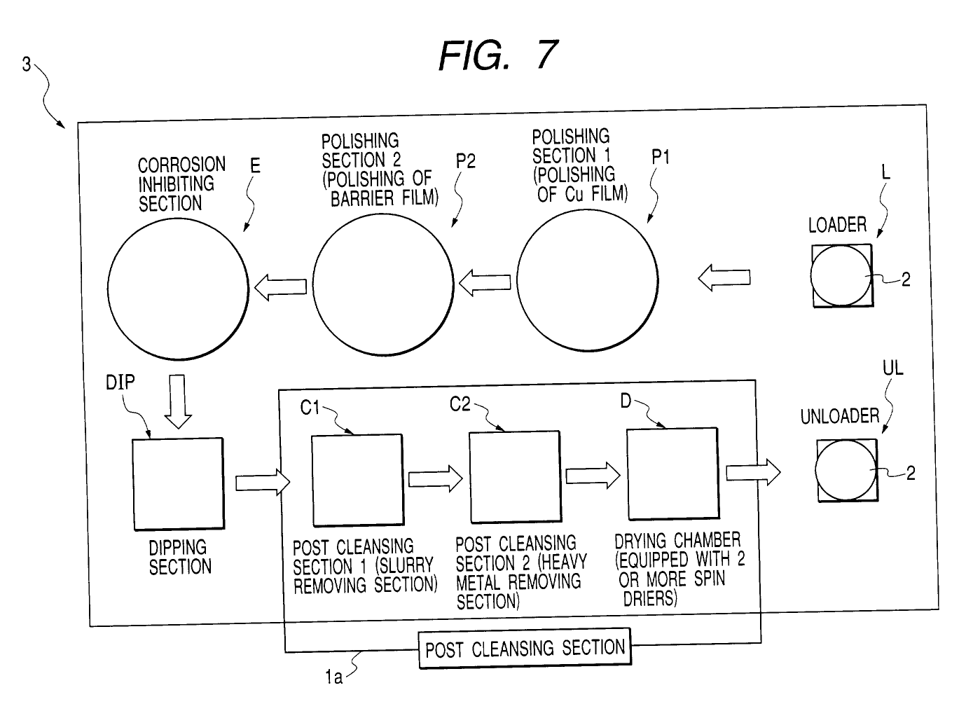

FIG. 7 illustrates one example of the whole constitution of the CMP apparatus 3 used in the fabrication method of a semiconductor integrated circuit device according to another embodiment of the invention.

This CMP apparatus 3 is a single-wafer CMP apparatus used for polishing of a conductive barrier film and a main conductor film made of copper which films will be described more specifically later. It is equipped with a loader L for housing therein plural wafers 2 having a main conductor film formed on the surface thereof; a polishing section 1 for polishing and planarizing the main conductor film; a polishing section 2 for polishing and planarizing the conductive barrier film; a corrosion inhibiting section E for subjecting the surface of the polished wafer 2 to anticorrosive treatment; a dipping section DIP for keeping the wafer 2 which has finished the anticorrosive treatment from drying out until post-CMP cleaning starts, wet; a post-CMP cleaning section 1a for subjecting the wafer which has finished the anticorrosive treatment to post-CMP cleaning; and an unloader UL for housing therein a plurality of the wafers which have finished the post-CMP cleaning. The post-CMP cleaning section 1a corresponds to the post-CMP cleaning apparatus 1 of Embodiment 1 and it has a brush cleaning chamber 1 for carrying out the above-described alkali cleaning, a brush cleaning chamber C2 for carrying out the above-described acid cleaning and a drying section D for drying. This drying section D is also equipped with two or more drying chambers as described in Embodiment 1. The whole post-CMP cleaning section 1a is surrounded with a light shielding wall so that the surface of the wafer 2 during cleaning is prevented from exposure to light. It is as if a dark room with its inside having 180 lux, preferably 100 lux or less. If the wafer 2 having a polishing solution attached to the surface thereof is exposed to light under a wet state, a short-circuit current flows to a pn junction owing to photovoltaic power of silicon, which causes dissociation of Cu ions from the surface of the Cu interconnect connected to the p side (+side) of the pn junction, thereby causing interconnect corrosion.

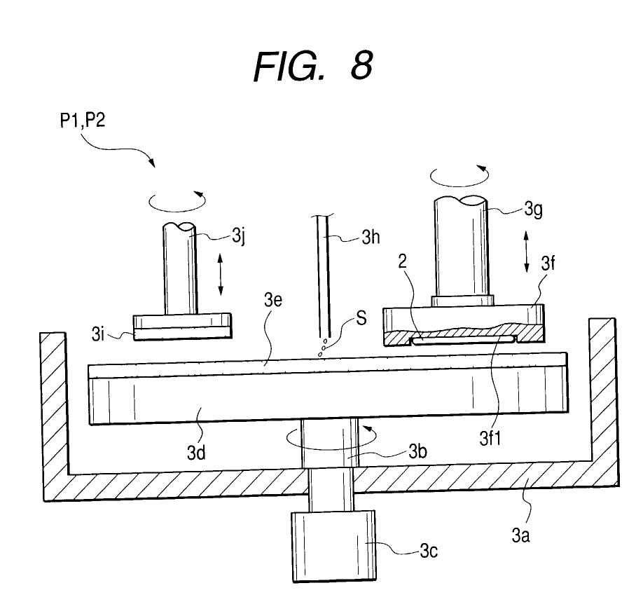

As illustrated in FIG. 8, the polishing sections P1,P2 of the CMP apparatus 2 have each a housing 3a having an opening at the upper portion thereof. At the upper end portion of a rotating shaft 3b attached to the housing 26a, a polishing platen 3d to be rotatively driven by a motor 3c is installed. The polishing platen 3d has, on the surface thereof, a polishing pad 3e formed by uniformly adhering thereto a synthetic resin having a number of pores. This polishing platen 3d is rotatively driven within a horizontal plane by a driving mechanism disposed below the platen.

These polishing sections P1,P2 have each a wafer carrier 3f for holding the wafer 2. A driving shaft 3g equipped with the wafer carrier 3f is, together with the wafer carrier 3f, rotatively driven by a motor (not shown) and at the same time, moved vertically above the polishing platen 3d.

By the wafer carrier 3f, the wafer 2 is held with its main surface, that is, polish surface down by a vacuum suction mechanism (wafer chuck, not illustrated) of the wafer carrier 3f. The wafer carrier 3f has, at the lower surface thereof, a retainer ring which is formed so as to surround the periphery of the wafer 2. This serves as a recess 34a to house the wafer 2 therein. If the wafer 2 is housed in this recess 3f1, its polish surface becomes on the same level with or a little projected from the lower end surface of the wafer carrier 3f. The wafer 2 is held by the wafer carrier 3f with its main surface (polish surface) down and pressed against a polishing pad 3e by a predetermined load.

Above the polishing platen 3d is disposed a slurry feed pipe 3h for feeding polishing slurry S between the surface of the polishing pad 3e and a polish surface of the wafer 2. By the polishing slurry S fed from the lower end of the pipe, the polish surface of the wafer 2 is chemically and mechanically polished. A polishing slurry obtained by dispersing or dissolving, in water, main components, for example, an abrasive such as alumina and an oxidizing agent such as aqueous hydrogen peroxide or an aqueous solution of ferric nitrate is employed as the polishing slurry S.

These polishing sections P1,P2 have each a dresser 3i as a tool for shaping (dressing) the surface of the polishing pad 3e. The dresser 3i has, at the lower end portion thereof, a base material to which diamond particles have been electrodeposited, by which the surface of the polishing pad 3e is cut periodically in order to prevent clogging with the polishing abrasive. The dresser 3i is attached to the lower end portion of the driving shaft 3j which moves vertically above the platen 3d and it is rotatively driven by a motor (not illustrated).

The surface of the polished wafer 2 is then subjected to anti-corrosive treatment at the corrosion inhibiting section E. The corrosion inhibiting section E has a similar constitution to that of the above-described polishing sections P1,P2. In this section, the polishing slurry is mechanically removed by pressing the main surface of the wafer 2 against the polishing pad 3e attached to the surface of the polishing platen. A chemical solution containing an anticorrosive such as benzotriazole (BTA) is then fed to the main surface of the wafer 2, whereby a hydrophobic protective film is formed at the surface portion of the copper interconnect formed on the main surface of the wafer 2.

The wafer 2 which has finished the anticorrosive treatment is temporarily stored in the dipping section DIP in order to prevent its surface from drying. The dipping section DIP serves to keep, until post-CMP cleaning starts, the wet state of the surface of the wafer 2 which has completed the anticorrosive treatment. It has, for example, a structure wherein a predetermined number of wafers 2 are dipped and stored in a dipping tank (stocker) having pure water allowed to overflow. It is possible to prevent corrosion of an inlaid interconnect made of copper more completely by supplying the dipping tank with pure water cooled enough not to allow substantial progress of electrochemical corrosion on the inlaid interconnect. A method other than the above-described storage of wafers in a dipping tank, for example, feeding them with pure-water shower may be adopted in order to prevent the wafer 2 from drying, insofar as it is capable of keeping at least the surface of the wafer 2 wet.

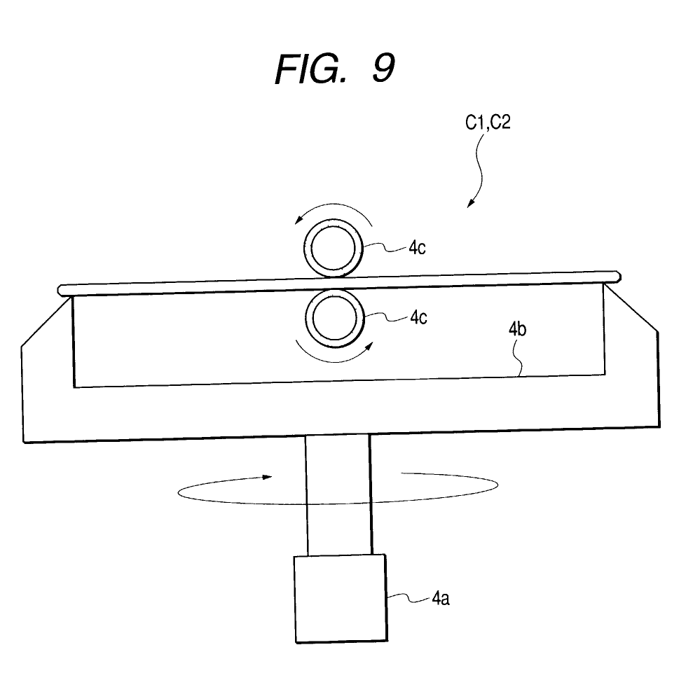

FIG. 9 is a scrub cleaning apparatus which is one example of the above-described brush cleaning chambers C1,C2. This scrub cleaning apparatus has a stage 4b to be rotatively driven by a motor 4a. The wafer 2 held on the stage 4b is rotated at a desired speed within a horizontal plane. This apparatus also has cylindrical brushes 4c which are pressed against the upper and lower surfaces of the wafer 2 rotating on the stage 4b. These brushes 4c are rotated at a desired speed within a plane vertical relative to the main surface of the wafer 2 by a rotation drive mechanism. The brushes 4c are supplied with the above-described cleaning solution through piping. The cleaning solution supplied to the brushes 4c ooze out little by little from the inside to the surface (contact surface with the wafer 2) of the brushes 4c formed of a porous product of a synthetic resin such as polyvinyl alcohol (PVA), thereby wetting the surface of the wafer 2 contacted with the brushes 4c.

The slurry adhered to the wafer 2 is removed by pressing the brushes 4c against the upper and lower surface of the wafer 2, respectively, and rotating them within a plane vertical relative to the main surface of the wafer 2 while rotating the wafer 2 within a horizontal plane. These brushes 4c are pressed against the wafer 2 at such a pressure to form a slight dent (for example, about 1 mm) in the tip of many protrusions (which will be described later) disposed on the surface of the brushes. The rotation speed of the wafer 2 is set, for example, at about 20 rpm while the rotation speed of the brushes 4c is set at, for example, about 120 rpm. By scrub cleaning of the both sides of the wafer 2 with the brushes 4 for a predetermined time, the slurry adhered to the surfaces can be removed.

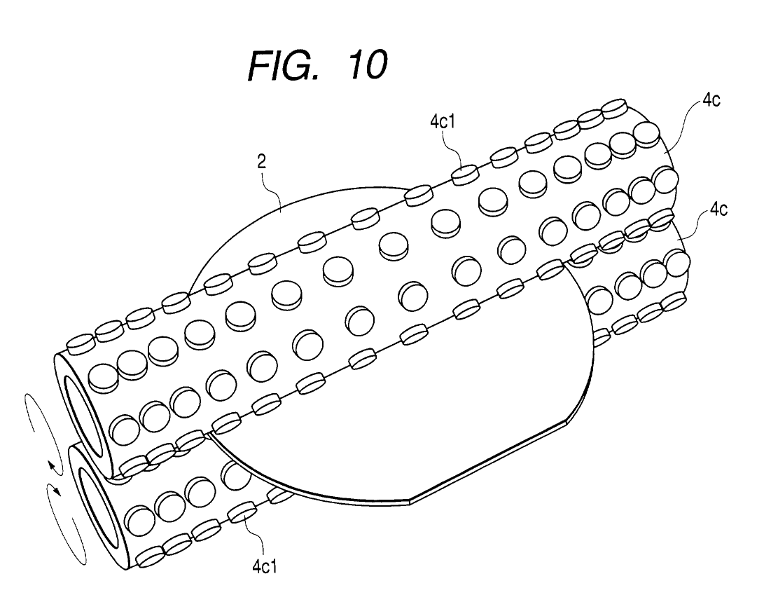

FIG. 10 is an enlarged perspective view of the above-described brushes 4c. As illustrated in the diagram, a number of minute cylindrical protrusions 4c1 are disposed at a predetermined distance on the surface of these brushes 4c, that is, on the contact surface with the wafer 2. The brushes 4c are formed of, for example, a porous product of a synthetic resin such as PVA. In this Embodiment 2, the number of the protrusions 4c1 shows an increase from the center toward both ends of each of the brushes 4c. In other words, the protrusions 4c1 are disposed such that their number is minimum in the center of the brush 4c and maximum at the both ends thereof.

When such brushes 4c are used, time of the central portion of the wafer 2 brought into contact with the central portion of the brushes 4c becomes longer than the time of the peripheral portion of the wafer 2 brought into contact with the end portions of the brushes 4c. On the contrary, however, because the protrusions 4c1 brought into contact with the wafer 2 are minimum in the number at the central portion of each of the brushes 4c and maximum in the number at the end portions thereof, the contact area between each of the brushes 4c and the wafer 2 is greater at the peripheral portion than at the central portion of the wafer 2. By such a structure, the value of contact time×contact area between each of the brushes 4c and the wafer 2 becomes substantially equal throughout the surface of the substrate, whereby the removed amount (etched amount) from the surface of the inlaid interconnect made of copper can be made uniform throughout the surface of the wafer 2.

According to the experiment made by the present inventors, the removed amount from the surface of the inlaid interconnect made of copper was made nearly uniform throughout the surface of the wafer 2 by optimizing the number of the protrusions 4c1 under the following conditions. The diameter of the wafer 2 used herein is, for example, about 125 mm, the rotation speed of the wafer 2 is, for example, about 22 rpm, and the diameter of the brush 4c is, for example, about 55 mm. The brush 4c was pressed against the wafer 2 at a pressure to form a dent of 1 mm in the contact surface with the wafer 2.

The wafer 2 was equally divided into ten from the center to the outermost periphery and the number of the protrusions brought into contact with each region was increased gradually from the center of the brush toward its end portion. At a rotation speed of the brush of 120 rpm, the optimal numbers of the protrusions of these ten regions were 1, 1, 2, 3, 3, 4, 5, 6, 7 and 8 (in the number), respectively in the order of from the center side of the wafer. At a rotation speed of the brush of 30 rpm, on the other hand, the optimal numbers of protrusions of the ten regions were 3, 3, 8, 8, 8, 8, 8, 8, 8 and 8 (in the number), respectively in the order of from the center side of the wafer.

For making uniform the contact time x contact area between each of the brushes 4c and the wafer 2 throughout the surface of the wafer, various means for changing the size, shape or number of the protrusions 4c1o can be adopted so that the contact area between the brush 4c and the wafer 2 becomes smaller toward the central portion of the wafer 2 and larger toward the peripheral portion of the wafer 2. For example, the diameters of the protrusions 4c1 on each of the brushes 4c are gradually increased from the central portion toward the both end portions of the brush 4c (or gradually decreased from the both end portions toward the central portion of the brush 4c).

It is also possible to, in stead of the above-described means of decreasing the contact area between the brush 4c and the wafer 2 from the peripheral portion of the wafer 2 toward the central portion, reduce the pressure of the brush 4c pressed against the surface of the wafer 2 from the peripheral portion of the wafer 2 toward the central portion (or increase the pressure from the central portion toward the peripheral portion). In this case, even if the contact area between the brush 4c and the wafer 2 is almost the same throughout the surface of the wafer 2, a similar effect is available.

In order to reduce the pressure of the brush 4c pressed against the surface of the wafer 2 from the peripheral portion of the wafer 2 toward its central portion, the height of the protrusions 4c1 or the diameter of the brush 4c may be decreased in the direction of from the both end portions of the brush 4c toward the central portion.

By optimizing a ratio of wafer rotation number/brush rotation number (hereinafter referred to as W/B ratio), the wafer 2 can be made uniform throughout its surface without changing the number of the protrusions 4c1 between the central portion and both end portions of the brush 4c. The results of the experiment made by the present inventors have revealed that post-CMP cleaning can be effectively conducted at a W/B ratio of 1.2 or greater for a roll-type cleaning apparatus and at W/B ratio of 2.0 or greater for a disk-type cleaning apparatus.

The technique for making uniform the removal amount of the wafer 2 within the polish surface upon the post-CMP cleaning as described above is disclosed by the present inventors in Japanese Patent Application No. 2000-176769.

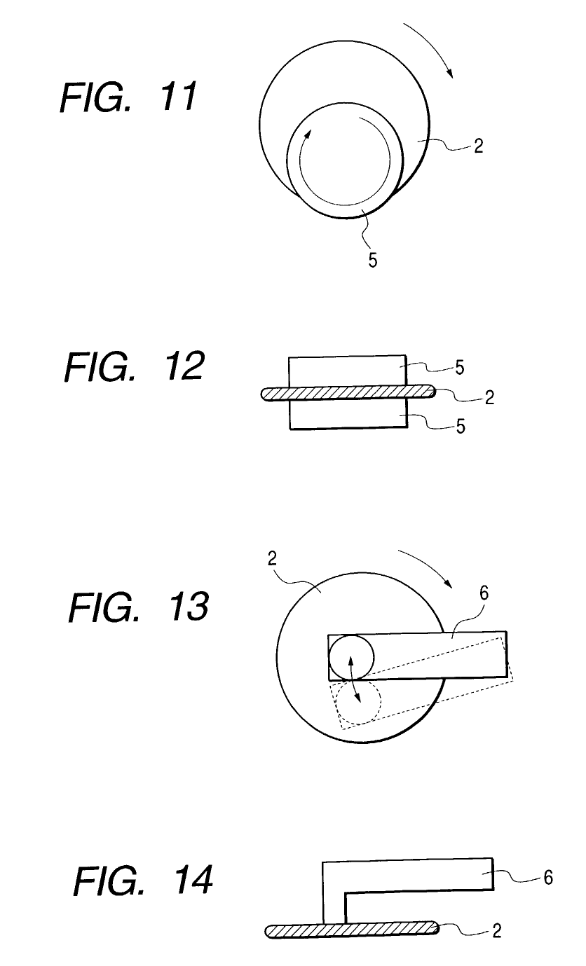

The above-described description of the post-CMP cleaning was made using a roll type cleaning system. The cleaning system is not limited to it, but can be modified. For example, a disk type cleaning system can be adopted for alkali cleaning, while a disk type or pen type cleaning system is employed for acid cleaning. FIGS. 11 and 12 illustrate one example of the disk type cleaning system. FIG. 11 is its plain view and FIG. 12 is its cross-sectional view. With disk brushes 5 of a flat circular shape disposed on the upper and lower sides of the wafer 2, the wafer 2 and disk brushes 5 are rotated within a horizontal plane, whereby the surface of the wafer 2 is cleaned. FIGS. 13 and 14 illustrate one example of the pen type cleaning system. FIG. 13 is its plain view, while FIG. 14 is its cross-sectional view. With a pen brush 6 disposed on the main surface (surface on which an inlaid interconnect is to be formed) of the wafer 2, the main surface and end surface of the wafer 2 are cleaned by rotating and oscillating the pen brush 6 while turning the wafer 2 within a horizontal plane. The pen brush 6 is suited for the removal of substances which remain after the upstream cleaning treatment (for example, roll type cleaning or disk type cleaning). The material of the brush portion of the disk brush 5 or pen brush 6 is similar to that described above.

The wafer 1 after the post-CMP cleaning is rinsed with pure water and spin dried. The wafer under a dried state is then housed in the unloader UL (refer to FIG. 7). A plurality of the wafers thus housed in the unloader are then transferred collectively to the next step.

The dipping section (substrate storing section) DIP for keeping the surface of the wafer 2 from drying during storage can be formed to have a light shielding structure so as to prevent exposure of the surface of the wafer 2 during storage to an illumination light. This makes it possible to avoid generation of a short-circuit current due to photovoltaic power effect. The dipping section DIP has gained a light-shielding structure by covering the dipping tank (stocker) with a light-shielding sheet, thereby decreasing the illumination inside of the dipping tank (stocker) to 500 lux or less, preferably 300 lux or less, more preferably 100 lux or less.

Immediately after polishing, i.e. just before starting of an electrochemical corrosive reaction by an oxidizing agent in the polishing slurry remained on the surface, the wafer may be transferred to the drying section to remove the water content from the polishing slurry by forced drying. In this case, the wafer 2 polished in the polishing sections P1,P2, immediately after polishing, i.e. just before starting of an electrochemical corrosive reaction by an oxidizing agent in the polishing slurry remained on the surface, is transferred to the drying section, where the water content in the polishing slurry is removed by forced drying. The wafer 2 which is still kept dry is then transferred to the post-CMP polishing section 1a, where it is subjected to post-CMP cleaning. After rinsing with pure water and spin drying, it is housed in the unloader UL. During just after polishing until initiation of post-CMP drying, the surface of the wafer 2 is kept dry so that the starting of the electrochemical corrosion reaction is inhibited, making it possible to effectively prevent the corrosion of an interconnect made of copper.

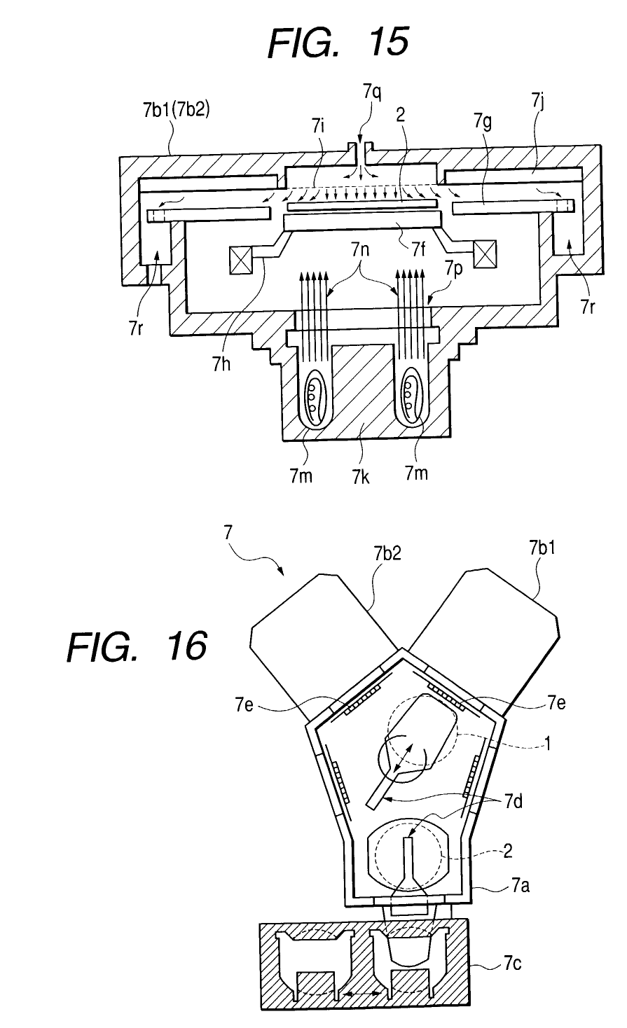

FIGS. 15 and 16 are a cross-sectional view and a plain view of one example of a plasma treatment apparatus 7 used for the fabrication method of a semiconductor integrated circuit device of this Embodiment 2, respectively. This plasma treatment apparatus 7 is an apparatus used for the formation of a cap insulating film and for reduction before formation of the cap insulating film after CMP polishing and post-CMP cleaning. This plasma treatment is disclosed by the present inventors in Japanese Patent Application No. Hei 11(1999)-226876.

This plasma treatment apparatus 7 uses, for example, “P5000” (trade name; product of AMAT). In the plasma treatment apparatus 7, a load lock chamber 7a is equipped with two treatment chambers 7b1, 7b2 and a cassette interface 7c. The load lock chamber 7a has therein a robot 7d to transfer the wafer 2. Between the load lock chamber 7a and the treatment chambers 7b1,7b2, a gate valve 7e is provided to keep the high vacuum state of the load lock chamber 7a even during treatment.

The treatment chambers 7b1,7b2 each has therein a susceptor 7f to hold the wafer 2, a baffle plate 7g to regulate a gas flow, a support member 7h to support the susceptor 7f, a mesh-like electrode 7i arranged opposed to the susceptor 7f, and an insulation plate 7j arranged nearly opposed to the baffle plate 7g. The insulation plate 7j serves to suppress parasitic discharge in an unnecessary region outside of the region between the susceptor 7f and the electrode 7i. On the back side of the susceptor 7f, a lamp 7m is arranged in a reflection unit 7k. Infrared ray 7n emitted from the lamp 7m passes through a quartz window 7p and is illuminated to the susceptor 7f and wafer 2. By this infrared ray, the wafer 2 is heated. The wafer 2 is disposed with the face up on the susceptor 7f (with the main surface, that is, a surface on which an inlaid interconnect is to be formed, up).

The treatment chambers 7b1, 7b2 has an interior capable of being highly evacuated. A treatment gas and high-frequency power are supplied through a gas port 7q. The treatment gas is supplied to the vicinity of the wafer 2, passing through the mesh-like electrode 7i. The treatment gas is discharged from a vacuum manifold 7r. By controlling the feed flow rate and exhaust speed of the treatment gas, pressure is put under control. High-frequency power is applied to the electrode 7i to generate plasma between the susceptor 7f and the electrode 7i. As the high-frequency power, a frequency, for example, of 13.56 MHz is used.

In the treatment chamber 7b1, the above-described hydrogen plasma treatment and ammonia plasma treatment, for example, are conducted. Such hydrogen plasma treatment and ammonia plasma treatment may be carried out in separate plasma treatment chambers. In the treatment chamber 7b2, the above-described cap film (silicon nitride film) is deposited. Because the treatment chambers 7b1,7b2 are mechanically connected each other through the load lock chamber 7a, the wafer 2, which has finished hydrogen plasma treatment and ammonia plasma treatment, can be transferred to the treatment chamber 7b2 without causing vacuum break. Thus, plasma treatment (post treatment) and cap film formation can be carried out successively.

Plasma treatment (post treatment) is effected in the following manner. The wafer 2 is transferred from the cassette interface 7c to the load lock chamber 7a by a robot 7d. The load lock chamber 7a is evacuated fully to a pressure reduced state, and the wafer 2 is carried into the treatment chamber 7b1 by using the robot 7d. The gate valve 7e of the treatment chamber 7b1 is closed. After evacuation of the treatment chamber 7b1 to a sufficient degree of vacuum, a hydrogen gas or ammonia gas is introduced into the treatment chamber 7b1. The pressure is adjusted to maintain a predetermined pressure. An electric field is then applied from the high frequency source to the electrode 7i, whereby the surface of the wafer 2 is subjected to plasma treatment as described above. After a lapse of a predetermined time, the high-frequency electric field is stopped to terminate generation of plasma. The treatment chamber 7b1 is then evacuated and the gate valve 7e is opened to carry out the wafer 2 into the load lock chamber 7a by the robot 7d. Since the load lock chamber 7a is maintained under a high vacuum condition, the surface of the wafer 2 is not exposed to the air atmosphere.

In the next step, the cap film is formed, for example, as described below. First, by using the robot 7d, the wafer 2 is carried into the treatment chamber 7b2. The gate valve 7e of the treatment chamber 7b2 is closed and the treatment chamber 7b2 is evacuated fully to a sufficient vacuum degree. A mixed gas of silane (SiH₄), ammonia and nitrogen is then introduced into the treatment chamber 7b2 and the chamber is maintained at a predetermined pressure by pressure adjustment. An electric field is then applied to the electrode 7i from the high-frequency source to generate plasma and an insulating film for the cap film is deposited. After a lapse of a predetermined time, the high frequency electric field is stopped to terminate generation of plasma. The treatment chamber 7b2 is then evacuated and the gate valve 7e is opened to carry out the wafer 2 into the load lock chamber 7a by the robot 7d. The wafer 2 is then carried out to the cassette interface 7c by using the robot 7d.

A description will next be made of one example of a fabrication method of the semiconductor integrated circuit device of this Embodiment 2 which uses the above-described CMP apparatus 3 and plasma treatment apparatus 7. Here, the present invention is applied to the fabrication method of CMIS (complementary MIS)-LSI (large scale integrated circuit).

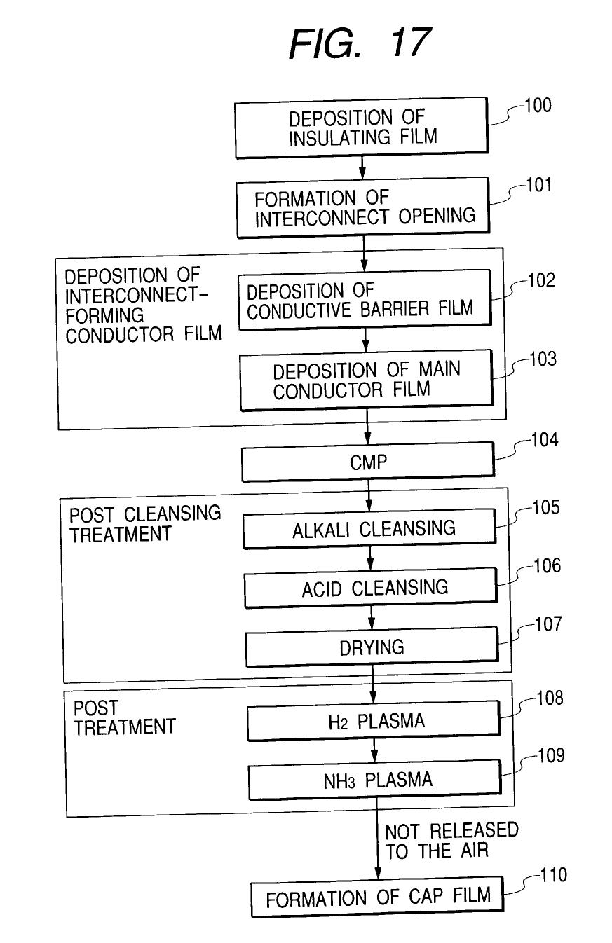

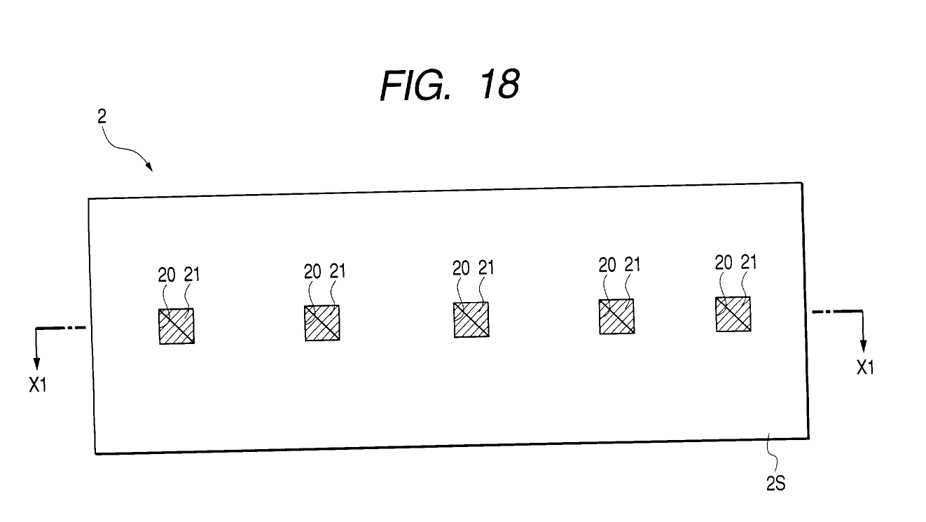

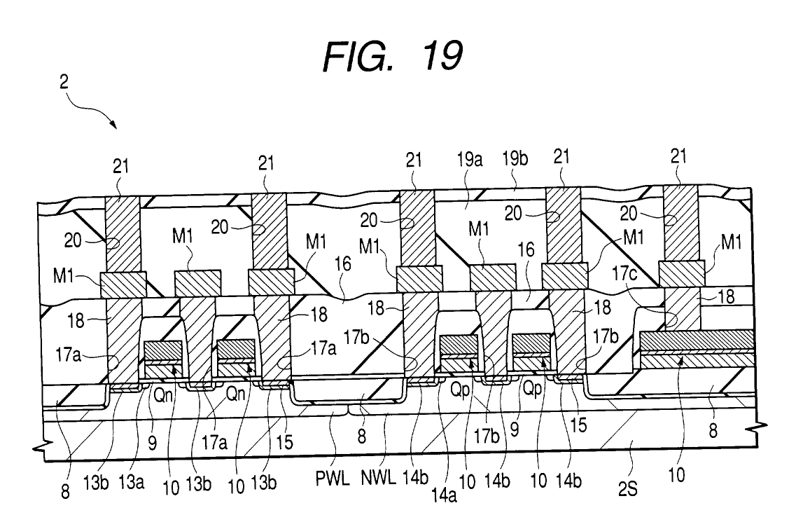

FIG. 17 is a flow chart of this fabrication method and FIGS. 18 to 27 are explanatory views of the fabrication method. FIG. 18 is a fragmentary plane view of the wafer 2 during fabrication, while FIG. 19 is the cross-sectional view of a line X1-X1 in FIG. 18. A semiconductor substrate (which will hereinafter be called “substrate” simply) 2S constituting the wafer 2 is made, for example, of a p type single crystal silicon having a specific resistance of about 1 to 10 Ωcm. In the main surface (a surface over which a device is to be formed) of the substrate 2S, a device isolation trench 8 is formed. In this device isolation trench 8, a silicon oxide film, for example, is embedded and a shallow groove isolation (SGI) or shallow trench isolation (STI) is formed. On the main surface side of the substrate 2S, a p-type well PWL and an n-type well NWL are formed. Boron, for example, is introduced in the p-type well PWL, while phosphorus is introduced in the n-type well NWL. In such formation regions of the p-type well PWL and n-type well NWL surrounded by the device isolation region 8, an nMISQn and a pMISQp are formed.

The nMISQn and the pMISQn each has a gate insulating film 9 which is made of a silicon oxide film of about 6 nm thick. This film thickness of the gate insulating film 9 means a film thickness in terms of silicon dioxide (which will be called “reduced film thickness”), which sometimes does not coincide with the actual film thickness. The gate insulating film 9 may be formed of a silicon oxynitride film in stead of a silicon oxide film. A silicon oxynitride film has higher effects for suppressing occurrence of an interface state in the film or reducing electron traps than a silicon oxide film so that it can improve hot carrier resistance of the gate insulating film 9, thereby improving dielectric strength. A silicon oxynitride film can be formed only by heat treating the semiconductor substrate 2S in a nitrogen-containing gas atmosphere such as NO, NO₂ or NH₃. Similar effects are available by forming the gate insulating film 9 made of silicon oxide on the surfaces of the p-type well PWL and n-type well NWL and heat treating the substrate 2S in the nitrogen-containing gas atmosphere, thereby causing segregation of nitrogen on the interface between the gate insulating film 9 and the substrate 2S.

The gate insulating film 9 may be formed of a silicon nitride film or a composite insulating film of a silicon oxide film and a silicon nitride film. If the gate insulating film 9 is made of silicon oxide and is thinned to less than 5 nm, especially less than 3 nm as a reduced film thickness, generation of a direct tunnel current or lowering of dielectric breakdown due to hot carriers caused by stress becomes apparent. Since a silicon nitride film has a higher dielectric constant than a silicon oxide film, its reduced film thickness becomes thinner than the actual film thickness. In other words, a silicon nitride film, even if it is physically thick, can gain the same capacitance as a silicon nitride film which is relatively thin. By forming the gate insulating film 9 from a single silicon nitride film or a composite film of it with a silicon oxide film, its effective film thickness can be made greater than a gate insulating film made of a silicon oxide film, thereby reducing the occurrence of a tunnel current leakage or lowering in dielectric breakdown due to hot carriers. In addition, since a silicon oxynitride film does not permit easy penetration of impurities therethrough compared with a silicon oxide film, variations of a threshold voltage due to diffusion of impurities in a gate electrode material to the side of the semiconductor substrate can be suppressed by forming the gate insulating film 9 from a silicon oxynitride film.

Silicon oxide (SiO₂) has a dielectric constant of 4 to 4.2, while silicon nitride (Si₃N₄) has a dielectric constant of 8. Provided that a dielectric constant of silicon nitride is twice as much as that of silicon oxide, a silicon nitride film of 6 nm thick has a reduced film thickness of 3 nm. In other words, a gate insulating film made of a silicon nitride film of 6 nm thick and a gate insulating film made of a silicon oxide film of 3 nm thick are equal in capacitance. The capacitance of a gate insulating film made of a composite film of a silicon oxide film of 2 nm thick and a silicon nitride film of 2 nm thick (reduced film thickness=1 nm) is equal to that of a gate insulating film made singly of a silicon oxide film of 3 nm thick.

The gate electrode 10 of the nMISQn and pMISQp is formed, for example, of a laminate of a low-resistance polycrystalline silicon film, a WN (tungsten nitride) film and a W (tungsten) film. The gate electrode 10 may be formed by using a laminate film obtained by depositing, over a low-resistance polycrystalline silicon film, a tungsten silicide film or a cobalt (Co) silicide film. Alternatively, an alloy of polycrystalline or single crystal silicon (Si) and germanium (Ge) may be employed as a material for the gate electrode 10. Over the gate electrode 10, a gate cap film 11 made, for example, of silicon oxide is formed. On the side surfaces of the gate electrode 10, side walls 12 made, for example, of silicon oxide are formed.

The n⁻ semiconductor region 13a and n⁺ semiconductor region 13b of the nMISQn are source·drain semiconductor regions for the nMISQn, into which phosphorus or arsenic has been introduced. The p⁻ semiconductor region 14a and p⁺ semiconductor region 14b of the pMISQp are source·drain semiconductor regions for the pMISQp, into which boron has been introduced. Over the surfaces of the n⁺ semiconductor region 13b and p⁺ semiconductor region 14b, a silicide layer 15 made, for example, of titanium silicide or cobalt silicide is formed.

An insulating film 16 is deposited over such a substrate 2S. This insulating film 16 is formed by a film having a reflow property high enough to fill a narrow space between the gate electrodes 10,10, for example, a BPSG (boron-doped phospho silicate glass) film. The insulating film 16 may be formed from an SOG (spin on glass) film to be formed by spin coating. The insulating film 16 has contact holes 17a to 17c formed therein. From the bottom of the contact holes 17a,17b, the upper surface of the silicide layer 15 is partially exposed. From the bottom of the contact hole 17c, the upper surface of the gate electrode 10 is partially exposed. Within each of the contact holes 17a to 17c, a plug 18 is formed. This plug 18 is formed, for example, by depositing, by CVD, a titanium nitride (TiN) film and a tungsten (W) film over the insulating film 16 including the insides of the contact holes 17a to 17c and then, removing unnecessary portions of the titanium nitride film and tungsten film from the insulating film 16 by CMP or etch-back to leave these films only inside of the contact holes 17a to 17c.

A first-level interconnect M1 is formed over the insulating film 16. This first-level interconnect M1 is formed, for example, of tungsten and electrically connected to the source·drain or gate electrode 10 of the nMISQn or pMISQp through the plug 18. Also over the insulating film 16, an insulating film 19a and then, an insulating film 19b are deposited in the order of mention so as to cover the first-level interconnect M1. The insulating film 19a is formed, for example, of an insulating film having a low dielectric constant such as organic polymer, while the insulating film 19b is formed, for example, of silicon oxide and it serves to secure the mechanical strength of the interlayer insulating film.

Examples of the organic polymer constituting the insulating film 19a include polyallyl ether (PAE) based materials such as “SiLK” (trade name; product of The Dow Chemical Co./USA; specific dielectric constant: 2.7, heat-resistant temperature: 490° C. or higher, dielectric breakdown: 4.0 to 5.0 MV/Vm) and “FLARE” (trade name; product of Honeywell Electronic Materials/USA; specific dielectric constant: 2.8, heat-resistant temperature: 40° C. or higher). The PAE-based material has high fundamental performance and is excellent in mechanical strength, thermal stability and low cost.

Examples of the material of the insulating film 19a include, in addition to the PAE based materials, SiOC-based materials, SiOF-based materials, HSQ (hydrogen silsequioxane)-based materials, MSQ (methyl silsesquioxane)-based materials, porous HSQ-based materials, porous MSQ-based materials and porous organic materials.

Examples of the SiOC-based materials includes “Black Diamond” (trade name; product of Applied Materials, Inc./USA; specific dielectric constant: 3.0 to 2.4, heat-resistant temperature: 450° C.), “CORAL” (trade name; product of Novellus Systems, Inc./USA; specific dielectric constant: 2.7 to 2.4, heat-resistant temperature: 500° C.), “Aurora 2.7” (trade name; product of ASM Japan; specific dielectric constant: 2.7, heat resistant temperature: 450° C.) and “p-MTES” (trade name; product of Hitachi Kaihatsu, specific dielectric constant: 3.2).

Examples of the HSQ-based materials include “OCD T-12” (trade name; product of Tokyo Ohka Kogyo; specific dielectric constant: 3.4 to 2.9, heat-resistant temperature: 450° C.), “FOx” (trade name; product of Dow Corning Corp./USA; specific dielectric constant: 2.9) and “OCL T-32” (trade name; product of Tokyo Ohka Kogyo; specific dielectric constant: 2.5, heat-resistant temperature: 450° C.).

Examples of the MSQ-based materials include “HSG-R7” (trade name; product of Hitachi Chemical, specific dielectric constant: 2.8, heat-resistant temperature: 650° C.), “OCD T-9” (trade name; product of Tokyo Ohka Kogyo; specific dielectric constant: 2.7, heat-resistant temperature: 600° C.), “LKD-T200” (trade name; product of JSR; specific dielectric constant: 2.7 to 2.5, heat-resistant temperature: 450° C.), “HOSP” (trade name; product of Honeywell Electronic Materials/US; specific dielectric constant: 2.5, heat-resistant temperature: 550° C.), “HSG-RZ25” (trade name; product of Hitachi Chemical, specific dielectric constant: 2.5, heat-resistant temperature: 650° C.), “OCL T-31” (trade name; product of Tokyo Ohka Kogyo; specific dielectric constant: 2.3, heat-resistant temperature: 500° C.) and “LKD-T400” (trade name; product of JSR; specific dielectric constant: 2.2 to 2, heat-resistant temperature: 450° C.).

Examples of the porous HSQ-based materials include “XLK” (trade name; product of Dow Corning Corp./USA; specific dielectric constant: 2.5 to 2), “OCL T-72” (trade name; product of Tokyo Ohka Kogyo; specific dielectric constant: 2.2 to 1.9, heat-resistant temperature: 450° C.), “Nanoglass” (trade name; product of Honeywell Electronic Materials/USA; specific dielectric constant: 2.2 to 1.8, heat-resistant temperature: 500° C. or higher) and “MesoELK” (trade name; product of Air Products and Chemicals Inc./USA; specific dielectric constant: 2 or lower).

Examples of the porous MSQ-based materials include “HSG-6211X” (trade name; product of Hitachi Chemical; specific dielectric constant: 2.4, heat-resistant temperature: 650° C.), “ALCAP-S” (trade name; product of Asahi Kasei Corp.; specific dielectric constant: 2.3 to 1.8, heat-resistant temperature: 450° C.), “OCL T-77” (trade name; product of Tokyo Ohka Kogyo; specific dielectric constant: 2.2 to 1.9, heat-resistant temperature: 600° C.), “HSG-6210X” (trade name; product of Hitachi Chemical; specific dielectric constant: 2.1, heat-resistant temperature: 650° C.), and silica aerogel (product of Kobe Steel; specific dielectric constant: 1.4 to 1.1).

Examples of the porous organic materials include “PolyELK” (trade name; product of Air Products and Chemicals, Inc./USA; specific dielectric constant: 2 or lower, heat resistant temperature: 490° C.).

In the insulating films 19a,19b, a through-hole 20 is perforated in order to partially expose the first-level interconnect M1. In this through-hole 20, a plug 21 made of tungsten, for example, is formed.

The insulating film 19a is formed by CVD when SiOC-based materials and SiOF-based materials are used and the insulating film 19b is also formed by CVD. When the above-described “Black Diamond” is employed, a mixed gas of trimethylsilane and oxygen is used as a raw material gas. When the above-described “P-MTES” is employed, a mixed gas of methyltriethoxysilane and N₂O is used as a raw material gas. When the other insulating materials having a low dielectric constant are employed, coating method is employed.

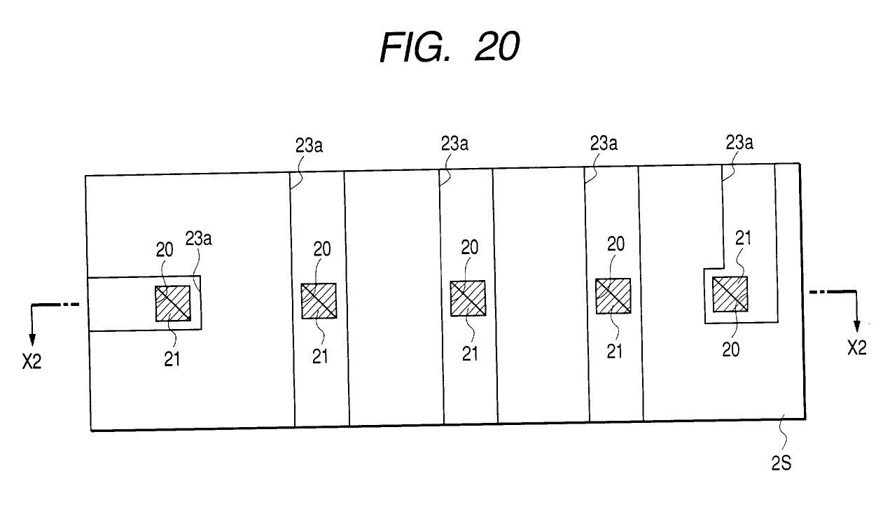

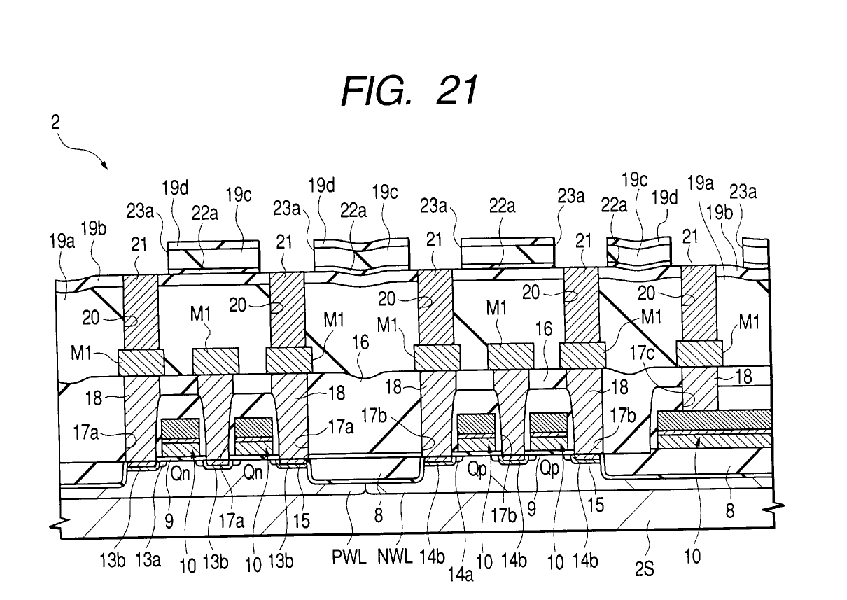

FIGS. 20 and 21 are, respectively, a fragmentary plane view of the wafer 2 and a cross-sectional view taken along a line X2-X2 of it in the fabrication step following FIGS. 18 and 19.

In this Embodiment 2, an insulating film 22a made, for example, of a silicon nitride film is deposited to a film thickness of 50 nm over a substrate 2S, which is as described above, by plasma CVD as illustrated in FIGS. 20 and 21. As the insulating film 22a, a silicon carbide (SiC), silicon carbonitride (SiCN) or silicon oxide film deposited by plasma CVD is usable instead of the silicon nitride film. Examples of the material for the silicon carbide film formed by plasma CVD include “BLOk” (trade name; product of AMAT, specific dielectric constant: 4.3). A mixed gas of trimethylsilane and helium, for example, is employed for its formation. Examples of the material for the silicon oxide film formed by CVD include “PE-TMS” (trade name; product of Canon, specific dielectric constant: 3.9). A mixed gas of trimethoxysilane and nitrogen oxide (N₂O), for example, is employed for its formation. Use of them can drastically decrease the dielectric constant compared with the use of a silicon nitride film, thereby decreasing interconnect capacitance and improving the operation speed of the resulting semiconductor integrated circuit device.

Over the insulating film 22a, an insulating film 19c and 19d are deposited successively (Step 100 in FIG. 17). The insulating film 19c is made of a material selected from insulating films of a low dielectric constant similar to those used for the insulating film 19a. The insulating film 19d is made of the same material as the insulating film 19b. By dry etching with a photoresist film as a mask, the insulating films 19d, 19c and 22a are selectively removed to form an interconnect trench (interconnect opening portion) 23a (Step 101 in FIG. 17). This interconnect trench 23a is formed by selectively etching the insulating films 19d,19c with the insulating film 22a as an etching stopper, and then etching the insulating film 2a. By forming a thin insulating film 22a below the insulating films 19c,19d in which the insulating trench 23a is to be formed, stopping etching once on the surface of this insulating film 22a and then, etching the insulating film 22a, it is possible to improve depth precision of the interconnect trench 23a without overetching the interconnect trench 23a.

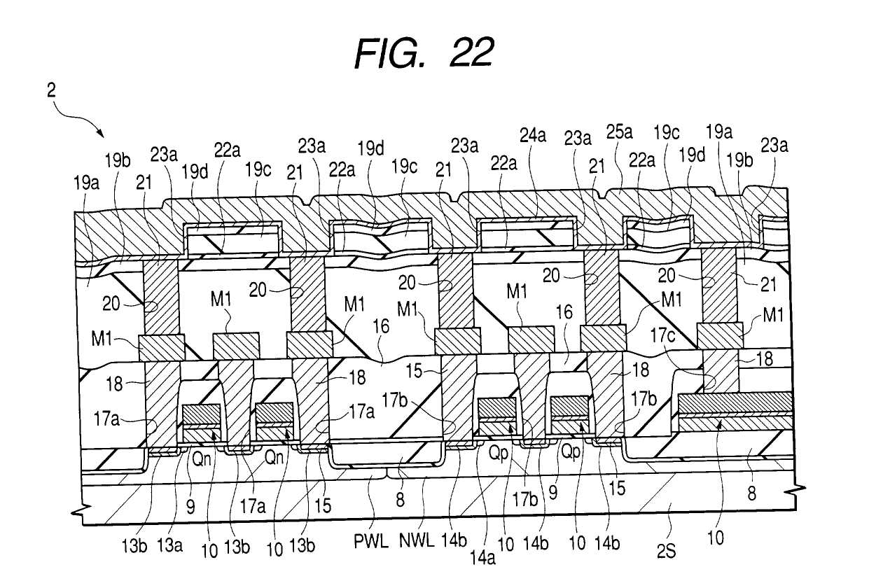

FIG. 22 is a fragmentary cross-sectional view of the wafer 2 during a fabrication step following FIGS. 20 and 21.

As illustrated in FIG. 22, a thin conductive barrier film 24a made, for example, of titanium nitride (TiN) is deposited over the insulating films 19c,19d including the inside of the interconnect trench 23a by sputtering (Step 102 in FIG. 17). This conductive barrier film 24a has functions of preventing diffusion of copper, a material for forming a main conductor film which will be described later, improving adhesion of the main conductor film with the insulating films 19c,19d and improving wetness of copper upon reflow of the main conductor film. As a film having such functions, a refractory metal nitride such as tungsten nitride (WN) or tantalum nitride (TaN) which hardly reacts with copper is preferably used instead of titanium nitride. A material obtained by adding silicon (Si) to a refractory metal nitride, or a refractory metal such as tantalum (Ta), titanium (ti), tungsten (W) or titanium tungsten (TiW) alloy which has poor reactivity with copper is also usable instead of titanium nitride. In this Embodiment, the conductive barrier film 24a having a thickness, at the thickest portion thereof, of 50 nm is used as an example. Investigation results of the present inventors have revealed that this conductive barrier film 24a can be made thinner or can even be eliminated, which is disclosed by the present inventors in Japanese Patent Application No. 2000-104015.

After deposition of a main conductor film 25a made, for example, of copper over the conductive barrier film 24a (Step 103 in FIG. 17), the wafer 2 is heat treated, for example, in a non-oxidizing atmosphere (for example, in a hydrogen atmosphere) at about 475° C. to cause reflow of the main conductor film 25a, thereby embedding inside of the interconnect trench 23a closely with copper.

In this Embodiment, the main conductor film 25a is made by plating method. Use of this plating method makes it possible to form the main conductor film 25a of a good quality with good embedding property at a low cost. The main conductor film 25a is formed by depositing a thin conductor film made of copper over the conductive barrier film 24a by sputtering, and allowing a relatively thick conductor film made of copper to grow, for example, by electroplating or electroless plating using a plating solution composed principally of copper sulfate.

Alternatively, the main conductor film 25a can be formed by sputtering. Although ordinary sputtering method is usable as sputtering for the formation of the conductive barrier film 24a and main conductor film 25a, sputtering having a high directivity such as long-throw sputtering or collimate sputtering is preferred in order to improve the embedding property and film quality. The main conductor film 25a can also be formed by CVD.

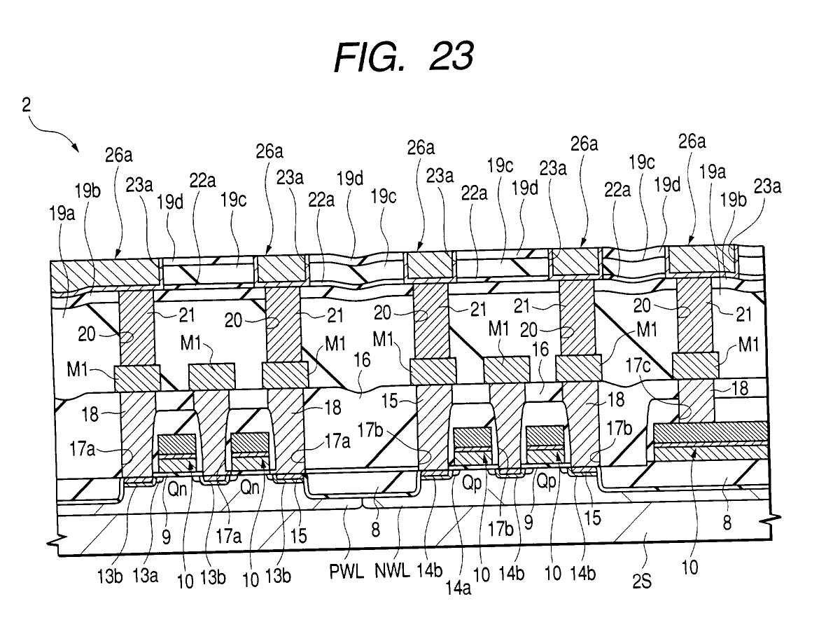

FIG. 23 is a fragmentary cross-sectional view of the wafer 2 during a fabrication step following FIG. 22.

An inlaid interconnect 26a composed mainly of copper is formed in the interconnect trench 23a by using the above-described CMP apparatus 3, where the main conductor film 25a on the wafer 2 is polished in the polishing section P1, the conductive barrier film 24a is then polished in the polishing section P2 (Step 104 in FIG. 17), and they are then cleaned with pure water.

While keeping the surface of the wafer 2 wet, the wafer 2 is immediately transferred to the post-CMP cleaning step. The wafer 2 is first subjected to alkali cleaning (Step 105 in FIG. 17). This alkali cleaning is conducted for removing foreign matters such as slurry upon CMP treatment. The acid slurry attached to the wafer 2 during CMP is neutralized to arrange the zeta potentials of the wafer 2, foreign matters and cleaning brush to the same direction. In order to eliminate an absorbing force between them, scrub cleaning (or brush cleaning) of the surface of the substrate 2S is conducted while supplying thereto an alkali chemical solution as week as pH 8 or greater. As an alkali chemical solution, aminoethanol (DAE: diluted amino ethanol, composition: 2-aminoethanol H₂NCH₂CH₂OH, concentration: about 0.001% to 0.1%, preferably 0.01%) is employed. This chemical solution has less etching action to copper and has a cleaning power equivalent to NH₄OH.

The wafer 2 is then subjected to acid cleaning (Step 106 in FIG. 17). This acid cleaning is conducted for the purpose of improving TDDB characteristic, removing remaining metals, reducing dangling bonds on the surface of the insulating film 19d and removing unevenness on the surface of the insulating film 19d. The surface of the wafer 2 is fed with an aqueous hydrofluoric acid solution to remove foreign matters (particles) therefrom by etching. TDDB characteristic can be improved only by supplying with an aqueous hydrofluoric solution, which is presumed to be due to removal of a damaged layer on the surface by acid cleaning and improvement in the adhesion on the interface. Brush scrub cleaning, for example, is employed for hydrofluoric acid (HF) cleaning and it is conducted under the selected conditions of an HF concentration of 0.5% and cleaning time of 20 seconds.

In the cleaning chamber C2, the wafer 2 is then rinsed with pure water. Then, it is transferred to the drying chamber D1 or D2 in the CMP apparatus 3, where drying (Step 107 in FIG. 17) such as spin drying, lamp anneal drying or IPA (isopropyl alcohol) paper drying is conducted. In each of the drying chambers D1,D2, the wafer 2 is treated one by one.

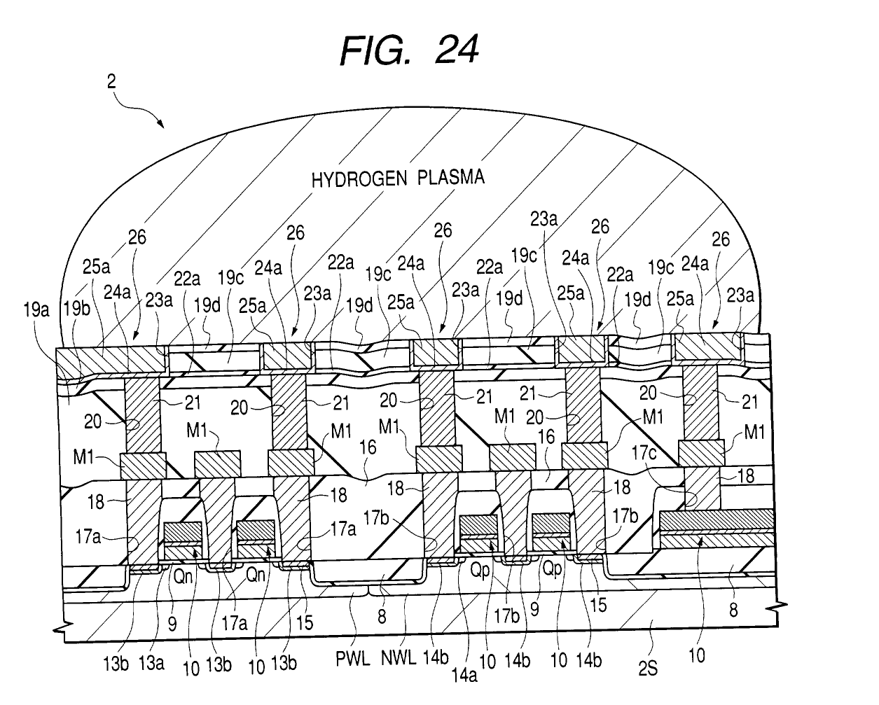

Then, post treatments (Steps 108,109 in FIG. 17) are conducted. As illustrated in FIG. 24, the surface of the wafer 2 (surface from which the inlaid interconnect 26 is exposed) is subjected to hydrogen plasma treatment. This hydrogen plasma treatment is conducted under the below-described conditions when the wafer 2 has, for example, a diameter of 8 inches (about 20 cm): treating pressure of 5.0 Torr (=6.6661×10² Pa), radio frequency (RF) power of 600 W, substrate temperature of 400° C., hydrogen gas flow rate of 500 cm³/min and treating time of 10 to 30 seconds. The distance between electrodes is set at 600 mils (15.24 mm).

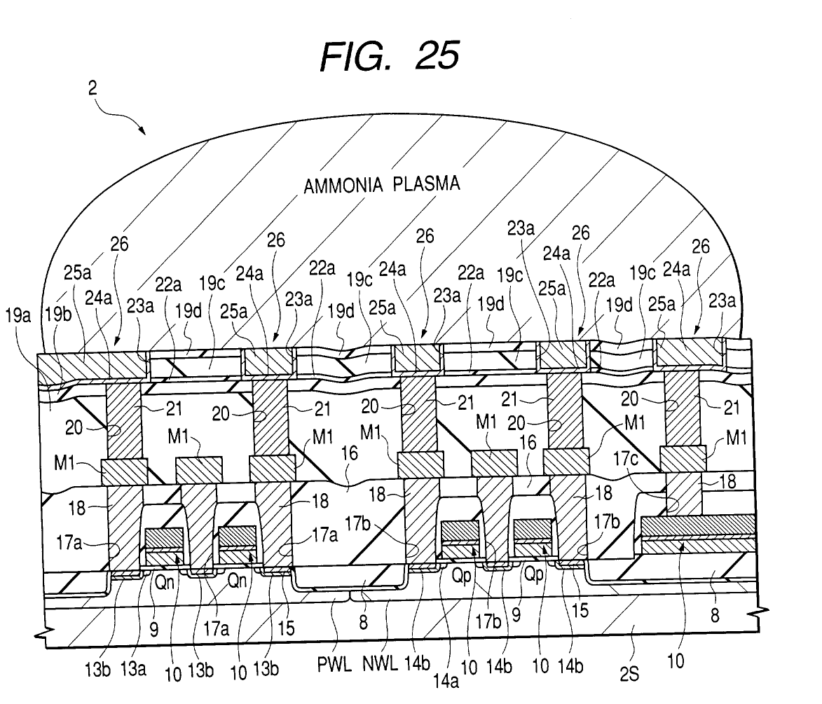

Without release of the wafer 2 to the air and successively after hydrogen plasma treatment 108, the surface of the wafer 2 (a surface from which the inlaid interconnect 26a is exposed) is subjected to ammonia (NH₃) plasma treatment as illustrated in FIG. 25. This ammonia plasma treatment is conducted, for example, under similar conditions to the hydrogen plasma treatment of Step 108 except that an ammonia flow rate is set at 200 cm³/min.

It is obvious that the plasma treatment conditions are not limited to the above-described ones. According to the investigation by the present inventors, the higher the pressure, the plasma damage can be reduced and the higher the substrate temperature, variations in the TDDB life within the substrate can be reduced and a longer life can be attained. It has also been found that the higher the substrate temperature, the higher the RF power and the longer the processing time, hillocks tend to appear on the surface of Cu. When such findings and variations in the conditions due to the difference in the apparatus constitution are taken into consideration, the plasma treatment conditions can be set within the following ranges: treating pressure of 0.5 to 6 Torr (=0.66661×10² to 7.99932×10² Pa), RF power of 300 to 600 W, substrate temperature of 350 to 450° C., hydrogen gas flow rate of 50 to 1000 cm³/min, ammonia gas flow rate of 20 to 500 cm³/min, treating time of 5 to 180 seconds and electrode-electrode distance of 150 to 1000 mils (3.81 to 25.4 mm).

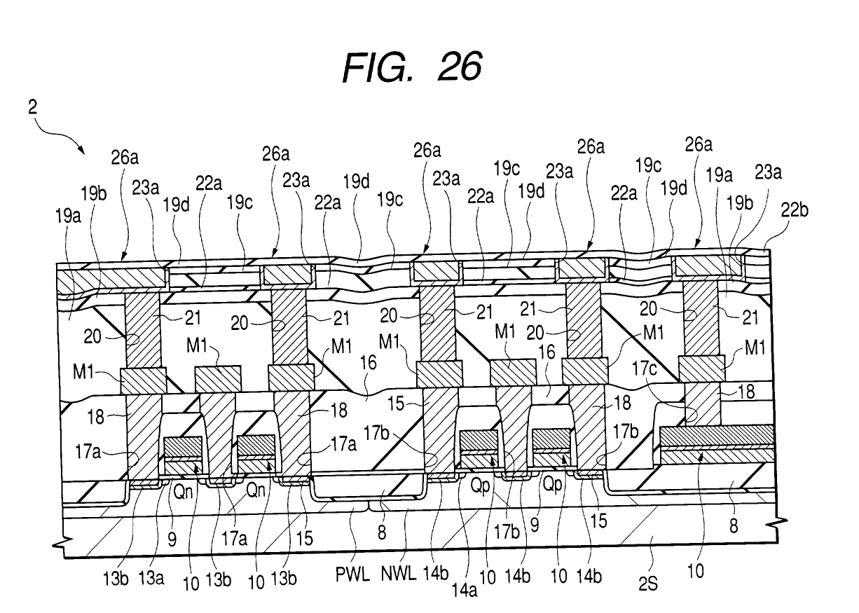

The above-described post-CMP treatment is followed by the formation of a cap insulating film (Step 110 in FIG. 17). Without release of the wafer 2 to the air and successively after the ammonia plasma treatment 109, an insulating film 22b (cap film) is deposited by CVD over the surface of the inlaid interconnect 26a and insulating film 19d as illustrated in FIG. 26. The insulating film 22b is made of the same material having the same thickness as the above-described insulating film 22a. It also has the same modification example as the insulating film 22a. For the post treatment and formation of the cap insulating film 22b, the plasma treatment apparatus 7 as described above is employed.

In this Embodiment, the wafer 2 is subjected successively to hydrogen plasma treatment and ammonia plasma treatment prior to the deposition of the cap insulating film 22b.

By ammonia plasma treatment, copper oxide (CuO, CuO₂) on the surface of the copper interconnect oxidized in CMP is reduced into copper (Cu). Also by this treatment, a copper nitride (CuN) layer for preventing copper silicidation upon set flow is formed over the surface (an extremely thin region) of the inlaid interconnect 26a. On the upper surface (an extremely thin region) of the insulating film 19d between interconnects, formation of SiN or SiH proceeds to compensate for the dangling bonds on the surface of the insulating film 19d. It also improves the adhesion between the cap film (silicon nitride film) and the inlaid interconnect 26a, and the insulating film 19d, thereby reducing the leak current through the interface. This effect contributes to an improvement in the TDDB life.

Hydrogen plasma has, on the other hand, a markedly high removing capacity of organic substances compared with ammonia plasma, as described by the present inventors in Japanese Patent Application No. Hei 11(1999)-226876 or Japanese Patent Application 2000-104015. This makes it possible to almost completely remove BTA contained in the slurry upon CMP, slurry components, organic acids used for post-CMP cleaning and organic residues formed during the process, thereby reducing the leak current through the interface. As a result, the TDDB life can be improved furthermore.

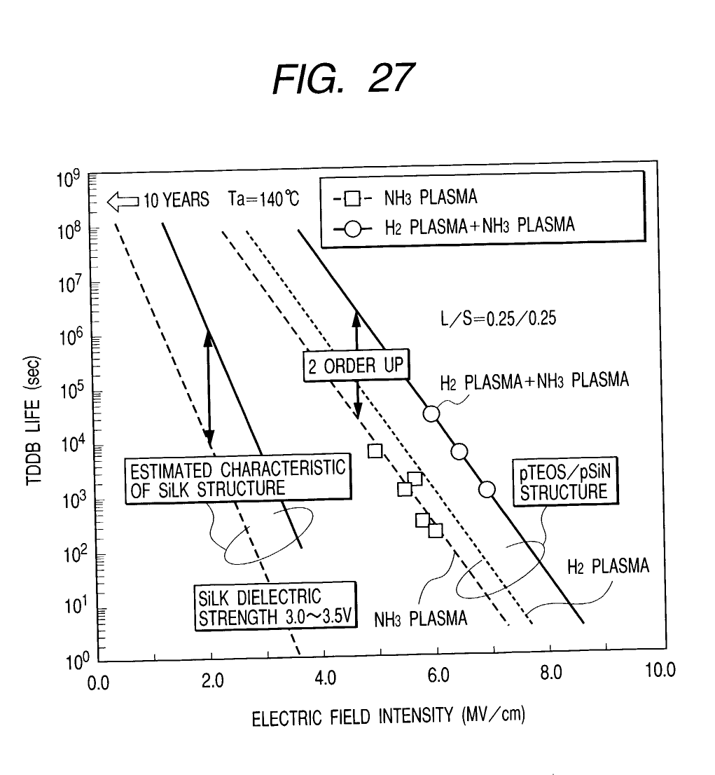

These hydrogen plasma treatment and ammonia plasma treatment carried out successively make it possible to accomplish reduction on the surface of the inlaid interconnect 26a composed mainly of copper, formation of a silicide-resistant barrier layer, and cleaning and SiH and SiN effects at the interface of the insulating film, thus realizing further improvement in reliability. FIG. 27 illustrates the TDDB characteristic upon combined use of hydrogen plasma treatment and ammonia plasma treatment in practice. CMP and post-CMP cleaning are conducted under similar conditions. It has been proved that when an interlayer insulating film is formed by depositing a silicon nitride film by plasma CVD over a silicon oxide film formed by plasma CVD using, for example, a TEOS (tetraethoxysilane) gas, the TDDB life is improved by about double digits when hydrogen plasma treatment and ammonia plasma treatment are used in combination compared with a case where only ammonia plasma treatment is conducted. This improvement in TDDB life brought by reduction is disclosed by the present inventors in Japanese Patent Application No. Hei 11(1999)-226876 or No. 2000-104015.

FIG. 27 shows estimated characteristics when an interlayer insulating film is formed of such a material having a low dielectric constant (such as the above-described SILK) as explained in this Embodiment, based on the fact the dielectric breakdown of SILK is about 4.0 to 5.0 MV/cm and also based on the evaluation experience of the TDDB characteristic of an organic SOG (spin on glass) interlayer structure. Under the operation environment of about 0.13 to 0.17 MV/cm for 10 years, reliability may be insufficient when ammonia plasma treatment is conducted singly. In this Embodiment using both hydrogen plasma and ammonia plasma, on the contrary, sufficient reliability can be secured under the above-described operation environment. Influence of reduction on the TDDB life when a low-dielectric-constant film is used as the interlayer insulating film is disclosed by the present inventors in Japanese Patent Application 2000-300853.

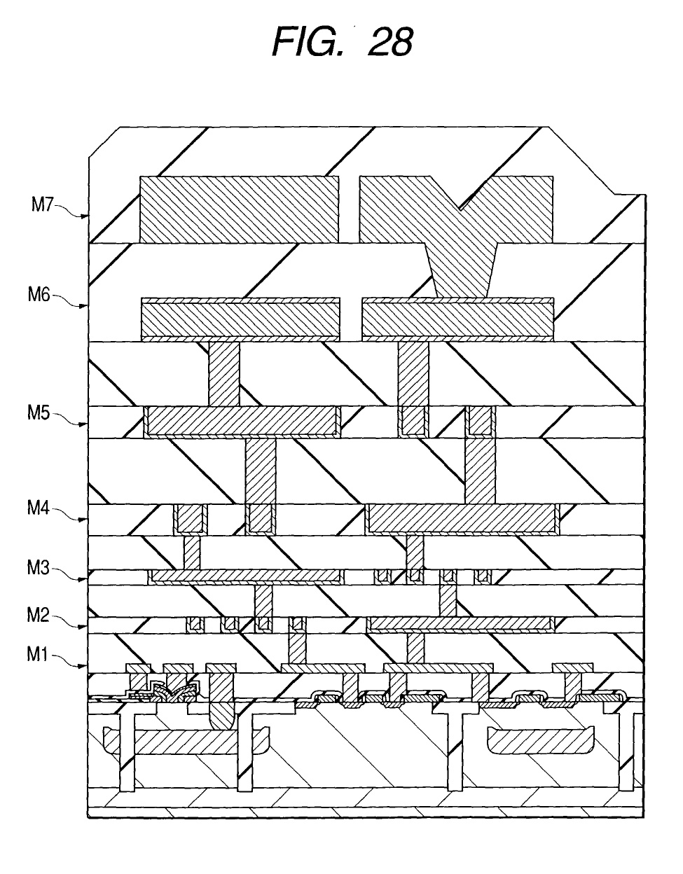

FIG. 28 illustrates one example of a CMIS-LSI which has been fabricated as described above and has finished formation of its seventh-level interconnect. Dimensions of each part will be described below.

The film thickness and the interconnect pitch (center-to-center distance between adjacent interconnects) of the first-level interconnect M1 are, for example, about 0.4 μm or about 0.25 μm. The second-level interconnect M2 to the fifth-level interconnect M5 are made by the above-described method employed for the formation of a Cu interconnect. With regards to the second-level interconnect M2 and third-level interconnect M3, the thickness of the conductive barrier film is, for example, about 0.05 μm; the thickness of the main conductor films is, for example, about 0.35 μm; and the interconnect width and the interconnect pitch are, for example, about 0.5 μm or about 0.25 μm. With regards to the fourth-level interconnect M4 and fifth-level interconnect M5, the thickness of the conductive barrier film is, for example, about 0.05 μm, the thickness of the main conductor film is, for example, about 0.95 μm, and the interconnect width and the interconnect pitch are, for example, about 1.0 μm or about 0.25 μm. The sixth-level interconnect M6 has a three layer structure, for example, composed of a tungsten film, an aluminum film and a tungsten film. The seventh-level interconnect M7 is made, for example, of an aluminum film. The pad of the seventh-level interconnect M7 has a bump electrode formed thereon or a bonding wire connected thereto, which is however not illustrated. One of the reasons why the seventh-level interconnect (M7) is formed of a laminate film of aluminum and tungsten is because the laminate film has been used so far as an uppermost layer of the usual semiconductor integrated circuit device not adopting a damascene interconnect structure and its reliability in connection to a bump electrode or bonding wire has been empirically proved. The through-hole for connecting the first-level interconnect M1 with the second-level interconnect M2 has a diameter, for example, of about 0.45 μm or about 0.25 μm. The through-hole for connecting the second-level interconnect M2 with the third-level interconnect M3 has a diameter, for example, of about 0.5 μm or about 0.25 μm. The through-hole for connecting the third-level interconnect M3 with the fourth-level interconnect M4 has a diameter, for example, of about 0.5 μm or about 0.25 μm. The through-hole for connecting fourth-level interconnect M4 with the fifth-level interconnect M5 has a diameter, for example, of about 1.0 μm or about 0.25 μm. The through-hole for connecting the fifth-level interconnect M5 with the sixth-level interconnect M6 has a diameter, for example, of about 0.5 μm or nearly 0.25 μm.

(Embodiment 3)

In Embodiment 3, a modification example of Embodiment 2 will be described. In this Embodiment, upon the above-described post-CMP cleaning, alkali cleaning is followed by reduction treatment, and then acid cleaning is conducted.

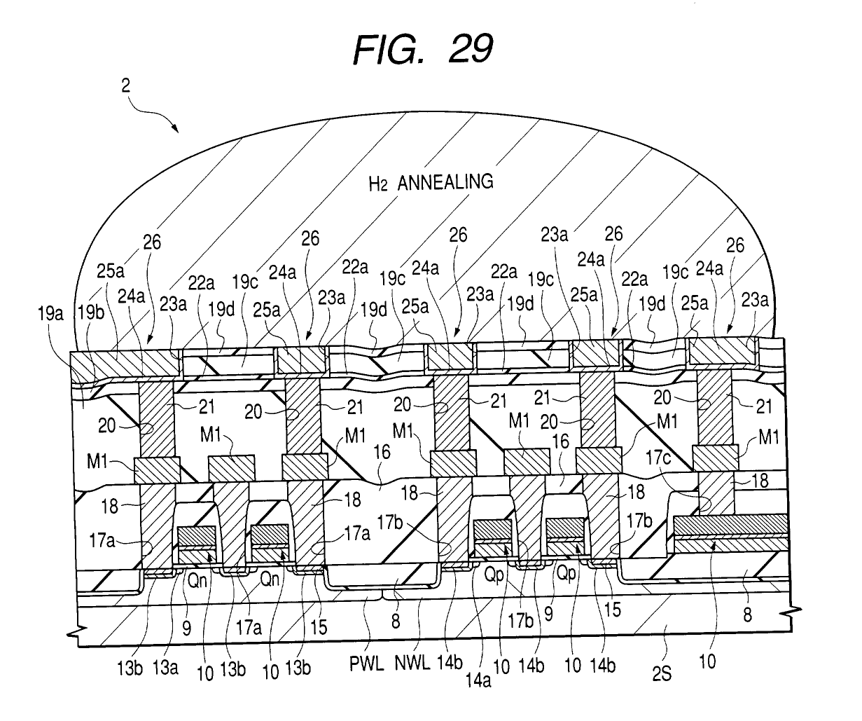

After Step 105 in FIG. 17, the wafer 2 is subjected to reduction treatment as illustrated in FIG. 29. This reduction treatment is effected by heat treating the wafer 2 in a hydrogen gas atmosphere, for example, at 200 to 475° C., preferably 300° C., for example, for 0.5 to 5 minutes, preferably about 2 minutes (hydrogen (H₂) annealing). By this heat treatment, a copper oxide film generated on the surface of the inlaid interconnect 26a can be reduced into copper, whereby etching of the inlaid interconnect 26a by the subsequent acid cleaning can be suppressed or prevented. This makes it possible to suppress or prevent an increase in the interconnect resistance, variations in the interconnect resistance and appearance of step difference simultaneously; and moreover to suppress or prevent generation of etch corrosion. When reduction treatment is not conducted, an organic matter such as BTA adhered onto the surface of the wafer 2 upon CMP may serve as a mask upon cleaning and disturb smooth etching of the surface layer of the insulating film 19d. An organic matter such as BTA adhered upon CMP can be removed when the reduction treatment is conducted as in this Embodiment so that the surface layer can be removed sufficiently and uniformly from the insulating film 19d. This enables a drastic improvement of the TDDB life of the semiconductor integrated circuit device.

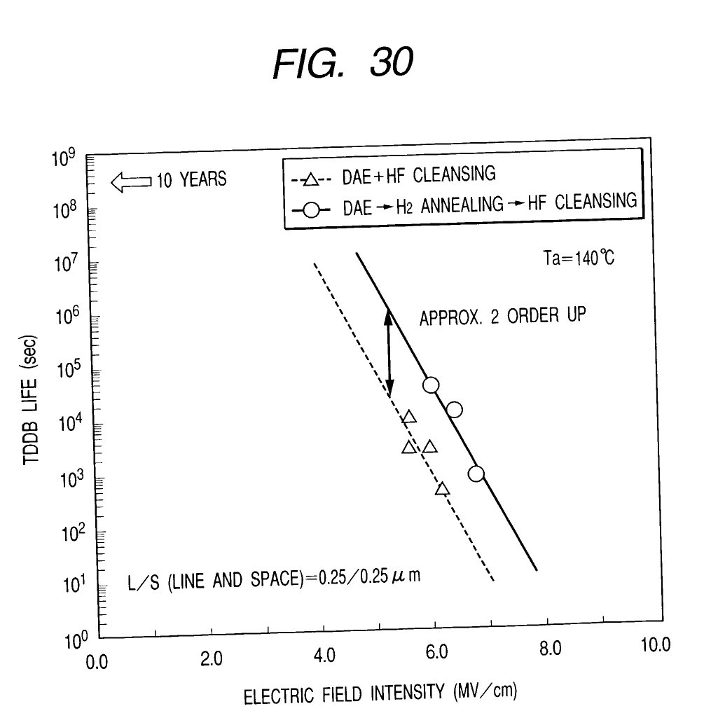

In FIG. 30, illustrated are results of the TDDB characteristic in this Embodiment. As a result of comparison, based on this diagram, in the TDDB characteristic between the sequence of alkali cleaning and acid cleaning and the sequence of alkali cleaning, hydrogen annealing and acid cleaning, the latter proves to be by about double digits better. The double-digit improvement of the TDDB life is quite effective, when the reliability of the inlaid copper interconnect structure using a low-dielectric-constant insulation material for the interlayer insulating film is taken into consideration. This improvement in the TDDB life by the introduction of hydrogen annealing between alkali cleaning and acid cleaning is considered to owe to the removal of organic matters such as BTA adhered during CMP. If acid cleaning is conducted without removing organic matters, the surface of the adjacent insulating film which is influential to the TDDB life cannot be cleaned (lift off) sufficiently. In this Embodiment, hydrogen annealing is followed by cleaning so that the surface layer of the insulating film can be sufficiently and uniformly lift off, making it possible to improve the TDDB life.

As described above, the occurrence of interconnect resistance proceeds in the order of the formation promotion of an oxide film by CMP, removal of a copper oxide film by an acid solution used upon hydrofluoric acid cleaning, increase (variation) in interconnect resistance and the occurrence of step difference. By hydrogen annealing just after completion of alkali cleaning, the copper oxide film on the surface of the interconnect, which film has appeared upon CMP, can be reduced into copper, whereby etching of the copper interconnect by acid cleaning can be suppressed or prevented, an increase or variation in the interconnect resistance and occurrence of step difference can be suppressed or prevented simultaneously, and moreover the generation of etch corrosion can be suppressed or prevented.

FIG. 31 is a graph illustrating dependence of interconnect resistance on hydrogen annealing when this Embodiment is applied. By introducing hydrogen annealing between alkali cleaning and acid cleaning, an interconnect resistance can be decreased by about 6%; and a variation in interconnect resistance can be decreased from 6.4% to 5.9%. In the above-described example, hydrogen annealing is conducted as reduction treatment. Not only hydrogen annealing but also hydrogen plasma or ammonia plasma treatment may be adopted as reduction treatment. This brings about, in addition to the above-described effects, a decrease in the reduction treatment time, leading to an improvement in the through-put. Advantages of hydrogen annealing over hydrogen plasma or ammonia plasma treatment reside in that the former has so far been adopted for device process and has solid accomplishments, and it can be conducted relatively easily because formation of a vacuum state is not required. Prior to or in concurrent with the post-CMP cleaning treatment, the surface of the wafer 2 may be subjected to pure-water scrub cleaning, pure-water ultrasonic cleaning, pure-running-water cleaning or pure-water spin cleaning, or the back side of the wafer 2 may be subjected to pure-water scrub cleaning.

In the above-described example, described was reduction treatment conducted after alkali cleaning but before acid cleaning in the post-CMP cleaning. The order of treatment is not limited to the above-described one but can be changed. For example, it is also possible to conduct, after CMP treatment, the above-described reduction treatment (hydrogen annealing), alkali cleaning and acid cleaning successively.

In the above-described example, described was a case where both alkali cleaning and acid cleaning are conducted upon post-CMP cleaning. The post-CMP cleaning is not limited to this. For example, only acid cleaning can be adopted. In this case, the above-described reduction treatment (hydrogen annealing) is preferably conducted prior to acid cleaning. The TDDB characteristic can be improved only by acid cleaning, because the characteristic at an interface can be improved by the removal of a damaged layer. In this case, the CMP apparatus 3 may be equipped with a reduction treatment section.

In the above-described example, upon post treatment, the hydrogen plasma treatment was followed by ammonia plasma treatment. The post treatment is not limited to it, but it is possible to carry out ammonia plasma treatment and then, continuously conducting hydrogen plasma treatment while maintaining a vacuum state. Ammonia plasma treatment alone is possible. In the latter cases, the interconnect resistance showed a decrease compared with the former case, but the TDDB life was improved.

After drying, the above-described hydrogen annealing may be conducted prior to post treatment. After drying, hydrogen annealing may be conducted, followed by only ammonia plasma treatment as post-treatment. In any case, hydrogen annealing was conducted the conditions, for example, of treating temperature of 200 to 475° C., preferably about 300° C. and treating time of 0.5 to 5 minutes, preferably about 2 minutes. This method is suited particularly for the formation, by plating, of a main conductor film made of copper for an inlaid interconnect. It is also suited for a case where hydrogen annealing is not conducted during or just before post-CMP cleaning. Hydrogen annealing treatment makes it possible to recrystallize copper, which has been formed by plating, thereby lowering the interconnect resistance. If a cap film (insulating film 22b) is deposited without this hydrogen annealing, peeling of the cap film may occur owing to heat stress. Hydrogen annealing can suppress or prevent it.

(Embodiment 4)

In this Embodiment 4, use of abrasive-free chemical mechanical polishing for the fabrication of a semiconductor integrated circuit device will be described.

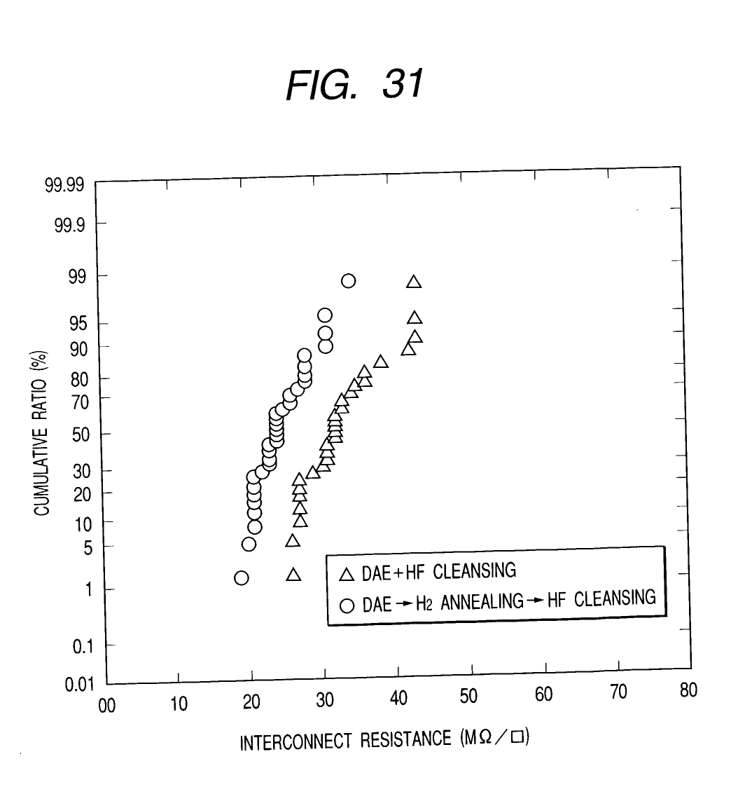

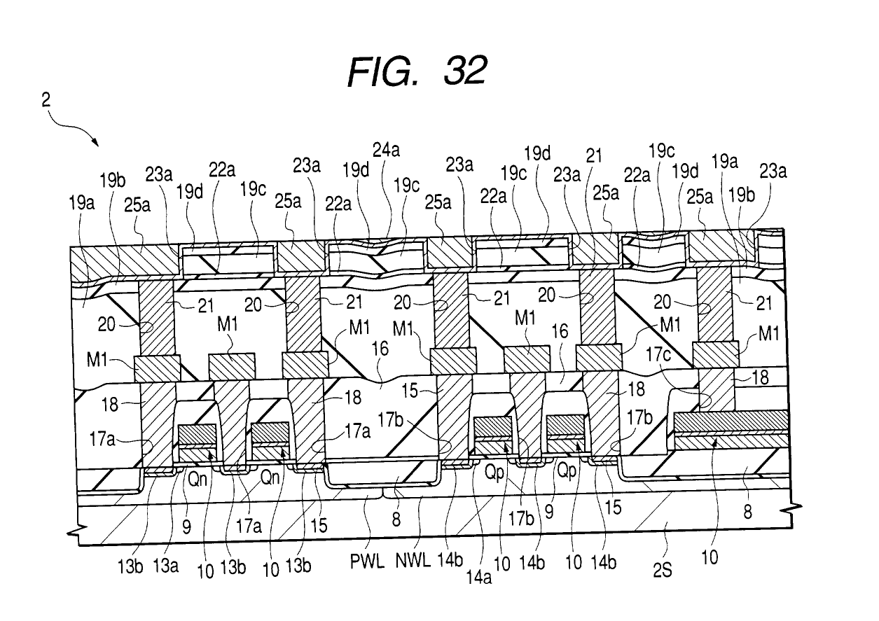

The wafer 2, which was described in FIG. 22, is placed on the polishing platen 3d in the polishing section P1 of the CMP apparatus and is subjected to chemical mechanical polishing using an abrasive-free slurry (abrasive-free chemical mechanical polishing), whereby a main conductor film 22a made of copper is removed from the outside of the interconnect trench 23a as illustrated in FIG. 32.

The term “abrasive-free chemical mechanical polishing” means chemical mechanical polishing using a polishing solution (slurry) containing 0.5 wt. % or less of an abrasive made of alumina, silica or like powder. As the polishing solution, that having an abrasive content of 0.1 wt. % or less, more preferably 0.05 wt. % or less, still more preferably 0.01 wt. % or less is preferred.

As the polishing solution, that having a pH adjusted to fall in a copper corrosion range, moreover, that having a composition adjusted to at least 5 as a polishing selectivity of the main conductor film 25a relative to the conductive barrier film 24a is employed. As such a polishing solution, a slurry containing an oxidizing agent and an organic acid can be given as an example. Examples of the oxidizing agent include hydrogen peroxide, ammonium hydroxide, ammonium nitrate and ammonium chloride, while those of the organic acid include citric acid, malonic acid, fumaric acid, malic acid, adipic acid, benzoic acid, phthalic acid, tartaric acid, lactic acid, succinic acid and oxalic acid. Of these oxidizing agents, hydrogen peroxide is suited for use for a polishing liquid because it is free of metal components and is not a strong acid. Citric acid which is ordinarily used as a food additive, has low toxicity, does slight harm as a waste fluid, is odorless and has high water solubility so that it is an organic acid suited for use for a polishing solution. In this Embodiment, used is a polishing solution obtained, for example, by adding 5 vol. % of hydrogen peroxide and 0.03 wt. % of citric acid to pure water and adjusting the abrasive content to less than 0.01 wt. %.

When chemical mechanical polishing is conducted using the above-described polishing solution, the copper surface is oxidized by the oxidizing agent and a thin oxide layer is formed on the surface. By the supply of a substance which makes the oxide soluble in water, the oxide layer is dissolved in water and elution of it as an aqueous solution occurs, leading to a decrease in the thickness of the oxide layer. The thinned portion of the oxide layer is exposed to the oxidizing substance again and the thickness of the oxide layer increases. These reactions occur in repetition, whereby chemical mechanical polishing proceeds. Chemical mechanical polishing using such an abrasive-free polishing solution is described in detail by the present inventors in Japanese Patent Application No. Hei 9(1997)-299937 and Japanese Patent Application No. Hei 10(1998)-317233.

The polishing is conducted under the following conditions, as one example, of a load of 250 g/cm², a wafer-carrier rotation speed of 30 rpm, a platen rotation speed of 25 rpm and a slurry flow rate of 150 cc/min. As a polishing pad, a hard pad (“IC1400”, trade name; product of Rodel/USA) is employed. Polishing is terminated when the main conductor film 25a is removed to expose the underlying conductive barrier film 24a. The terminal point is detected by detecting a change in rotation torque signal intensity of a platen or wafer carrier when a subject to be polished is changed from the main conductor film 25a to the conductive barrier film 24a. Alternatively, it is possible to make a hole through a part of the polishing pad and detect a terminal point based on a change in the reflection spectrum of a light from the surface of the wafer 2; or to detect based on a change in the optical spectrum of a slurry.

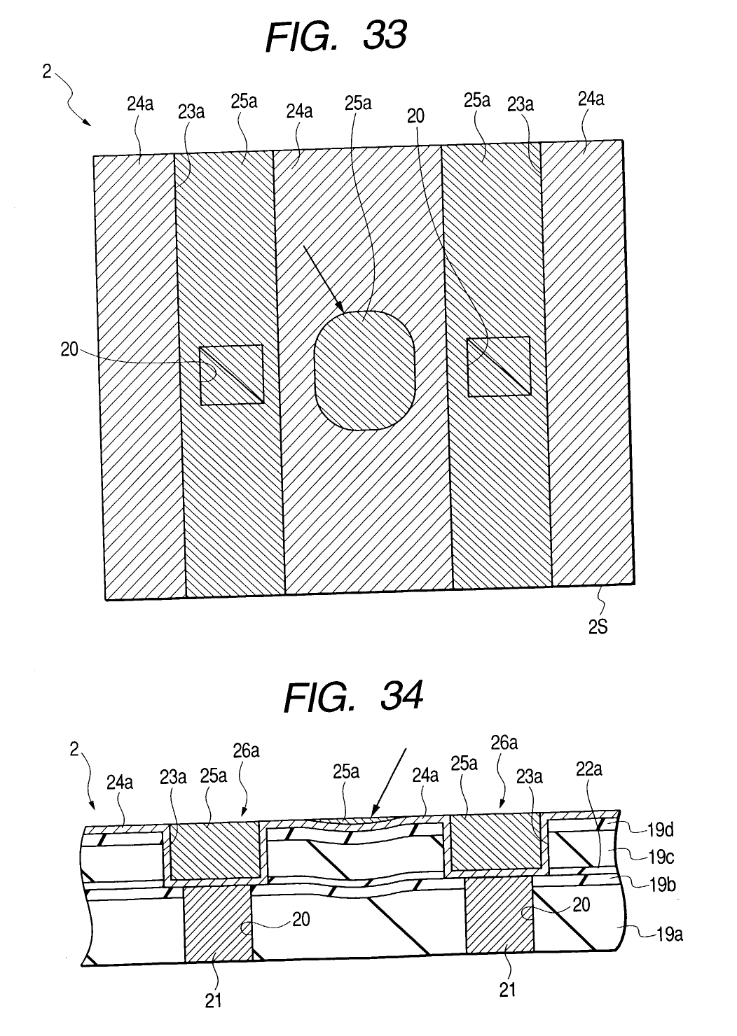

By the abrasive-free chemical mechanical polishing, most of the main conductor film 25a outside the interconnect trench 23a is removed to expose the underlying conductive barrier film 24a as described above. As is apparent from the enlarged views of FIGS. 33 and 34, however, the main conductor film 25a may remain without being completely removed from a dent (shown by an arrow) of the conductive barrier film 24a resulting from the underlying step difference.

The wafer 2 is then transferred from the polishing section P1 to the polishing section P2, both illustrated in FIG. 7, and is subjected to chemical mechanical polishing (abrasive-used chemical mechanical polishing) using a polishing solution (slurry) containing an abrasive in order to remove the conductive barrier film 24a outside of the interconnect trench 23a and the main conductor film 25a remaining partially on the conductive barrier film. The term “abrasive-used chemical mechanical polishing” as used herein means chemical mechanical polishing using a polishing solution (slurry) containing an abrasive made of alumina, silica or the like powder in an amount of 0.5 wt. % or greater. The polishing solution used in this Embodiment is not limited to but a mixture of 5 vol. % of hydrogen peroxide, 0.03 wt. % of citric acid and 0.5 wt. % of an abrasive with pure water. This polishing solution is fed to the polishing pad 3e of the polishing platen 3d through the above-described slurry feed pipe 3h.

In this abrasive-used chemical mechanical polishing, after removal of the main conductor film 25a left partially on the upper surface of the conductive barrier film 24a, the conductive barrier film 24a outside of the interconnect trench 23a is removed. Upon removal, polishing is conducted under the conditions so that a polishing selectivity of the main conductor film 25a relative to the conductive barrier film 24a would be lower than those employed upon the above-described abrasive-free chemical mechanical polishing, for example, 3 or less in order to suppress polishing of the surface of the main conductor film 25a inside of the interconnect trench 23a.

Polishing is conducted under the conditions, as one example, of a load of 120 g/cm², wafer carrier rotation speed of 30 rpm, platen rotation speed of 25 rpm and slurry flow rate of 150 cc/min. As the polishing pad, “IC1400” (trade name; product of Rodel) is employed. The polishing amount is set to correspond to the thickness of the conductive barrier film 24a and the terminal point of the polishing is controlled by the polishing time calculated from the thickness of the conductive barrier film 24a and the polishing speed.

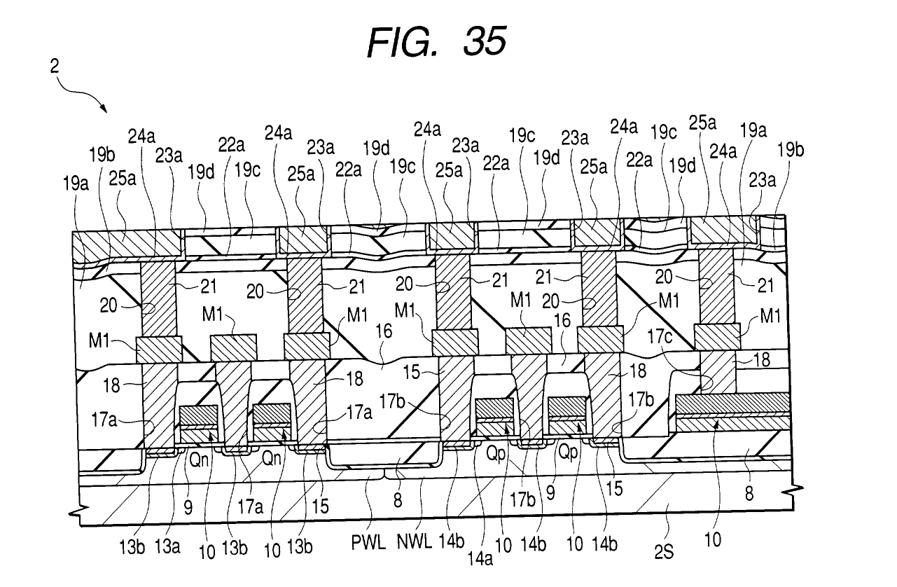

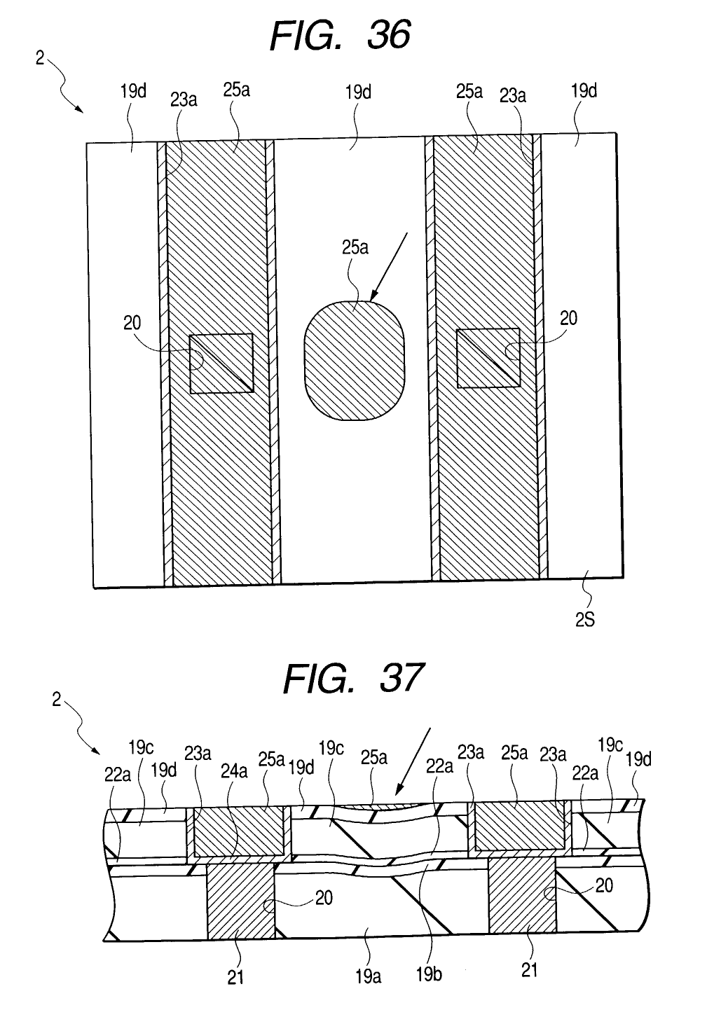

As illustrated in FIG. 35, most of the conductive barrier film 24a outside the interconnect trench 23a is removed to expose the underlying insulating film 19d by the above-described abrasive-used chemical mechanical polishing. As is apparent from the enlarged views in FIGS. 36 and 37, the conductive barrier film 24a remains in a dent (shown by an arrow) of the insulating film 19d, which has appeared due to the underlying step difference, without being removed completely by the above-described polishing.

Selective chemical mechanical polishing (the third step of CMP) is then conducted to remove the conductive barrier film 24a remaining partially on the insulating film 19d outside of the interconnect trench 23a, while suppressing the polishing of the main conductor film 25a inside of the interconnect trench 23a as much as possible. This selective chemical mechanical polishing is conducted under the conditions so that the polishing selectivity of the conductive barrier film 24a relative to the main conductor film 25a would be at least 5 or more; and under the conditions so that a ratio of the polishing speed of the insulating film 19d to the main conductor film 25a would be greater than 1.

For the selective chemical mechanical polishing, used is a mixture of an anticorrosive with a polishing solution containing an abrasive in an amount of 0.5 wt. % or greater, which has been used ordinarily for abrasive-used chemical mechanical polishing. The term “anticorrosive” as used herein means a chemical capable of preventing or suppressing a progress of polishing by forming an anticorrosive protective film on the surface of the main conductor film 25a. Examples include BTA derivatives such as benzotriazole (BTA) and BTA carboxylic acid, dodecyl mercaptane, triazole and tolyltriazole. Of these, BTA is particularly effective for the formation of a stable protective film.

When BTA is used as an anticorrosive, sufficient effect is available by adding it usually in an amount of 0.001 to 1 wt. %, preferably 0.01 to 1 wt. %, more preferably 0.1 to 1 wt. % (in three portions), though depending on the nature of the slurry. A mixture of the polishing solution used in the second step of CMP, that is, abrasive-used chemical mechanical polishing, with 0.1 wt. % of BTA as an anticorrosive is used in this Embodiment, but the polishing solution usable in this Embodiment is not limited to this mixture. To this mixture, polyacrylic acid or polymethacrylic acid, or ammonium salt thereof, or ethylene diamine tetraacetic acid (EDTA) may be added as needed in order to avoid lowering in the polishing speed by the addition of the anticorrosive. Chemical mechanical polishing using a slurry containing such an anticorrosive is described in detail by the inventors of present application in Japanese Patent Application Nos. Hei 10(1998)-209857, Hei 9(1997)-299937 and Hei 10(1998)-317233.

This selective chemical mechanical polishing is conducted in the polishing section P2 of the CMP apparatus 3 successively after completion of the abrasive-used chemical mechanical polishing. The polishing solution added with an anticorrosive is fed to the surface of the polishing pad 3e through the slurry feed pipe 3h. Polishing are conducted under the conditions of, as one example, load of 120 g/cm², wafer carrier rotation speed of 30 rpm, platen rotation speed of 25 rpm and slurry flow rate of 190 cc/min.

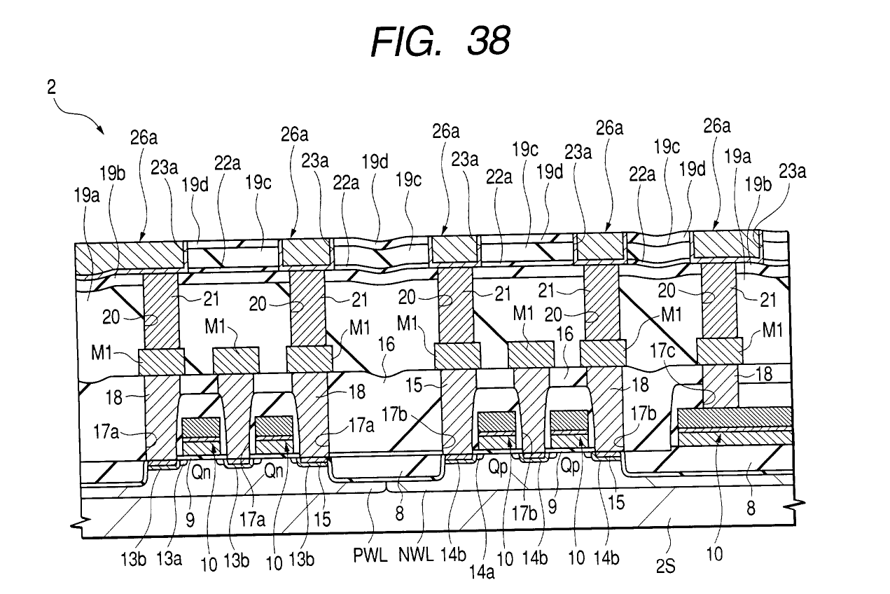

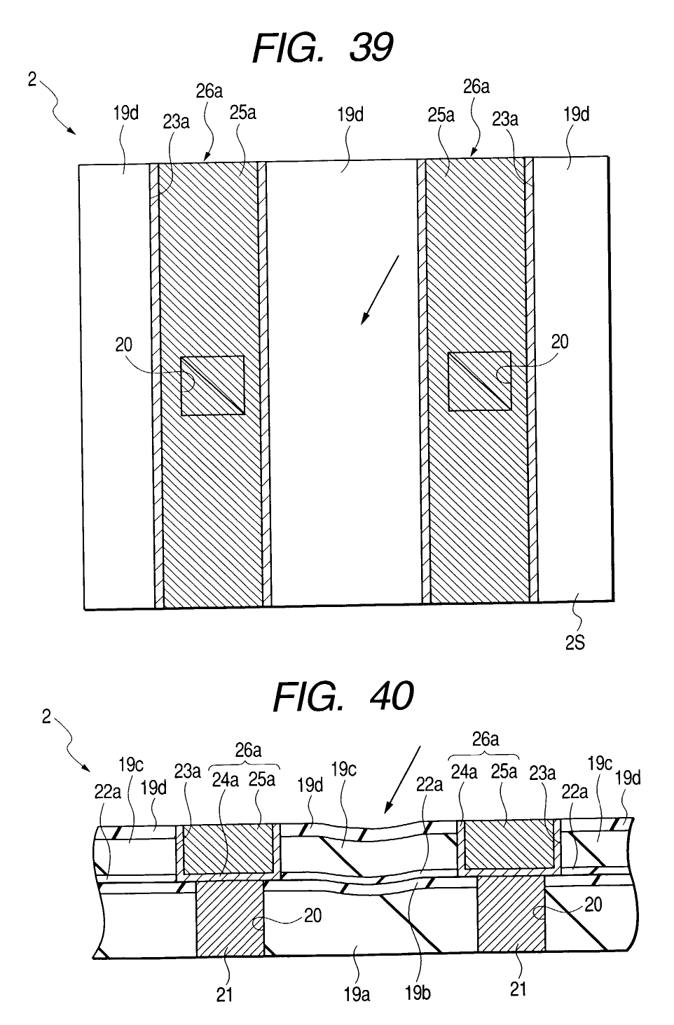

As illustrated in FIGS. 38, 39 and 40, by the selective chemical mechanical polishing, the conductive barrier film 24a outside the interconnect trench 23a is removed completely and an inlaid interconnect 26a is formed inside of the interconnect trench 23a.

On the surface of the wafer 2 having the inlaid interconnect 26a formed thereon, a slurry containing abrasive particles and metal particles such as Cu oxide remains. To remove this slurry residue, the wafer 2 is cleaned with BTA-containing pure water in a clean station. This pure water cleaning may be used in combination with megasonic cleaning in which oscillation at a frequency of 800 kHz or higher is applied to the polishing solution to release the slurry residue from the surface of the wafer 2. The wafer 2 is then transferred from the polishing section P2 to the post-CMP cleaning section while keeping it wet to prevent the surface from drying. In the cleaning chamber C1, scrub cleaning with a cleaning solution containing 0.1 wt. % of NH₄OH is conducted, followed by scrub cleaning with pure water in the cleaning chamber C2. As described above, the whole post-CMP cleaning section is covered with a light shielding wall, whereby corrosion of the inlaid interconnect 26a owing to exposure, to light, of the surface of the wafer 2 during cleaning can be prevented.

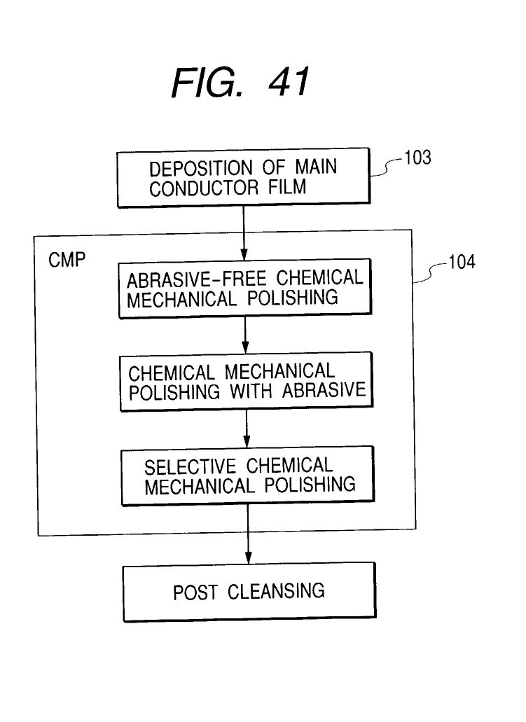

The wafer 2, after completion of the scrub cleaning (latter cleaning), is dried in the drying chamber D1 or D2 equipped with a drier and then, transferred to the subsequent step. The steps after drying are similar to those in Embodiment 1. FIG. 41 is a flow chart illustrating a part of the formation process of the inlaid interconnect 26a. Steps other than it are similar to those described in Embodiments 1 to 3.

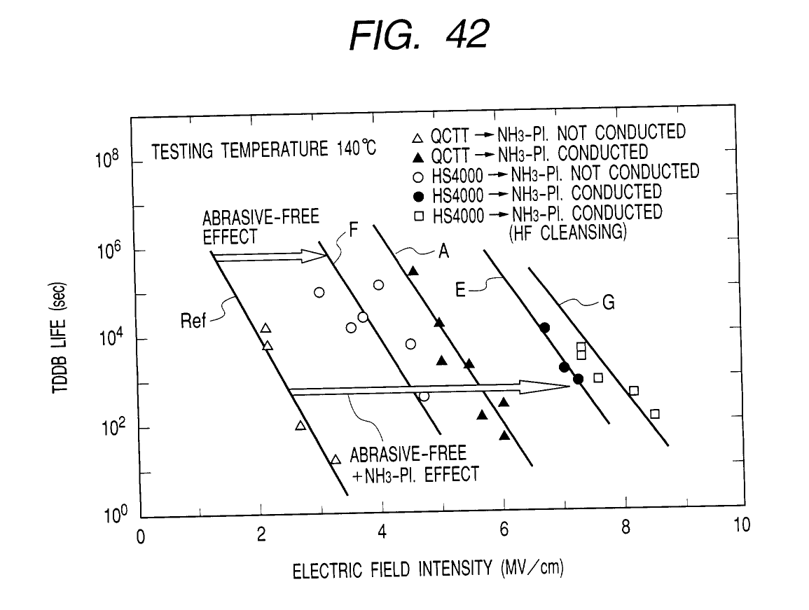

In this Embodiment, the TDDB life can be improved further compared with that in Embodiment 2. FIG. 42 is a graph showing the TDDB life in this Embodiment. The data of this Embodiment is indicated by line E. For reference, data (line Ref) of a CMP-free case and data (line A) when abrasive-used chemical mechanical polishing is conducted (Embodiment 2) are shown together. As line F suggests, only abrasive-free chemical mechanical polishing without ammonia plasma treatment brings about an improvement in TDDB characteristic. This improvement in TDDB life even without using an abrasive is presumed to owe to a reduction in the damage on the silicon oxide film. In the abrasive-used CMP, an abrasive (e.g. alumina) having a particle size (secondary particle size) of 2 to 3 μm contained in the slurry causes microscratches, giving a damage to the surface of the silicon oxide film (insulating film 19d). In the abrasive-free CMP, on the other hand, the slurry does not contain an abrasive or if any, contains a little, so that damage can be reduced greatly, whereby the TDDB characteristic is presumed to be improved.

(Embodiment 5)

In this Embodiment, upon acid cleaning (Step 106 in FIG. 17) in the post-CMP cleaning of Embodiment 1, the above-described organic acid or a mixture of hydrofluoric acid and the organic acid is used as a chemical solution. Except for use of such a chemical solution, this Embodiment is similar to the above-described Embodiments 1 to 4. When citric acid, for example, is used as the organic acid, brush scrub cleaning can be conducted while setting the citric acid concentration at 5% and cleaning time at 45 seconds.

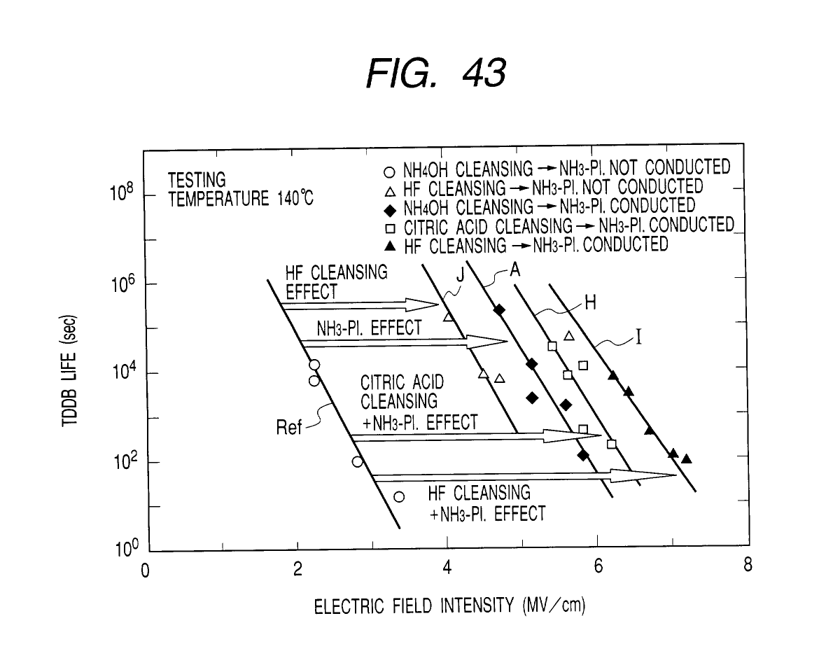

Employment of organic acid cleaning makes it possible to remove the damage layer which has appeared on the surface by CMP, thereby improving the TDDB life. FIG. 43 is a graph showing the TDDB life in this Embodiment. The data showing the use of citric acid are indicated by line H, while data showing the use of HF cleaning are indicated by line I. For reference, data showing treatment-free case (line Ref) and data (line A) of Embodiment 2 are also indicated together. Use of the organic acid is also effective for removal of only metal ions without adversely affecting the underlying film. In other words, impurities such as Fe, K and Ca can be removed selectively.

(Embodiment 6)

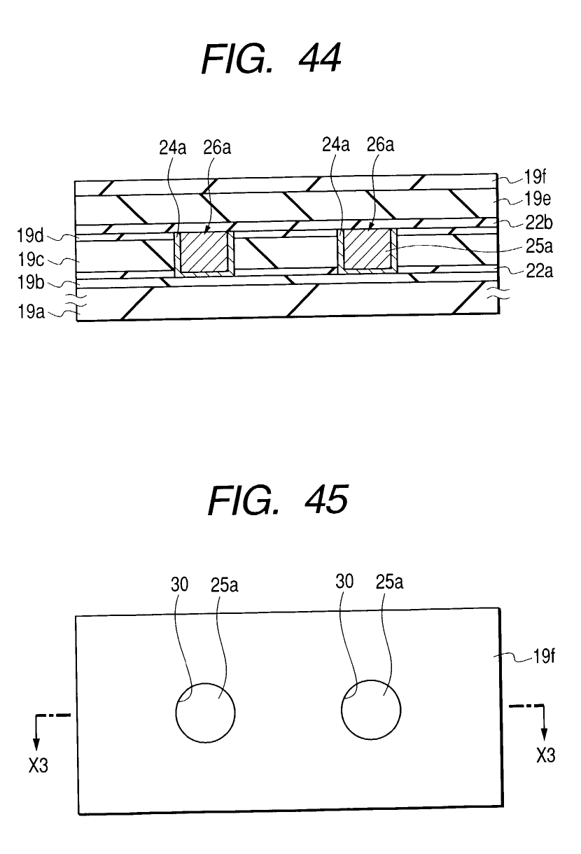

FIGS. 44 to 47 are plain view and cross-sectional view illustrating the fabrication method of a semiconductor integrated circuit device according to Embodiment 6 of the invention. In FIGS. 44 to 47, illustrated is only the interconnect portion.

As illustrated in FIG. 44, after formation of the inlaid interconnect 26a and insulating film 22b for cap film as in Embodiments 1 to 5, formed thereover are a low-dielectric-constant insulating film 19e made of a silicon oxide film and an insulating film 19f made of a silicon oxide film formed by plasma CVD using TEOS as a raw material gas.

The low-dielectric-constant insulating film 19e is constituted of a silicon oxide insulating film having a specific dielectric constant (ε) of 3.0 or less, for example, a coating type insulating film such as an inorganic SOG film using hydrogen silsesquioxane as a raw material or an organic SOG film using both tetraalkoxysilane and alkyl alkoxysilane as raw materials, or a fluorocarbon polymer film formed by plasma CVD. Use of such a low-dielectric-constant silicon oxide film makes it possible to reduce an interconnect-interconnect parasitic capacitance, thereby promoting an improvement in the operation speed of the semiconductor integrated circuit device.

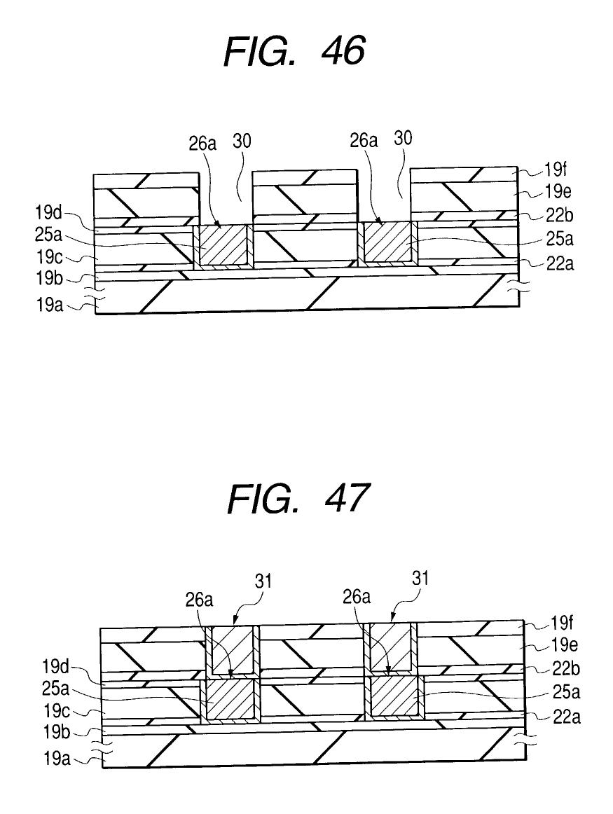

According to the patterns as illustrated in FIG. 45, through-holes 30 are then opened. Photolithography and etching are employed for opening of the through-holes 30. FIG. 46 is a cross-sectional view taken along a line X3-X3 in FIG. 44. The low-dielectric-constant insulating film 19e has a rough film surface structure and many Si—OH bonds. It has already been understood empirically that a film formed over such a low-dielectric-constant film has poor film quality or interface condition; and that a conductive barrier film (e.g. titanium nitride) formed without any treatment is inferior in TDDB characteristic. In order to overcome such drawbacks, therefore, an exposed portion of the insulating film 19e inside of the through-hole 30 is then subjected to ammonia plasma treatment as described in the above-described Embodiment. This treatment modifies the Si—OH bonds on the surface, thereby converting the into Si—O—N bonds as described above.

As illustrated in FIG. 47, a plug 31 made, for example, of titanium nitride and tungsten is formed inside of the through-hole 30. As in Embodiments 1 to 5, Si—O—N bonds are released upon deposition of titanium nitride, which improves the interface between titanium nitride and the low-dielectric-constant insulating film 19e, thereby improving adhesion property. It is needless to say that such plasma treatment conducted for the inside of the through-hole 30 can be applied to an interconnect trench.

Instead of ammonia plasma treatment, hydrogen plasma treatment or plasma treatment with a mixture of nitrogen, argon or helium may be employed. The ammonia plasma treatment and hydrogen plasma treatment may be used in combination. Combined use can improve the effect further. Steps other than those described above are conducted as in Embodiments 1 to 5.

In an ashing step for removing the photoresist film after the through-hole 30 is opened, the surface of the inlaid interconnect 26a on the bottom of the through-hole 30 is sometimes oxidized. A technique for removing such an oxidized layer is described, for example, in Japanese Patent Laid-Open No. Hei 11(1999)-16912.

(Embodiment 7)

In this Embodiment, fabrication using the dual damascene method will be described. The term “dual damascene method” means a technique having a step of simultaneously embedding both a hole and an interconnect trench with the same conductive material.

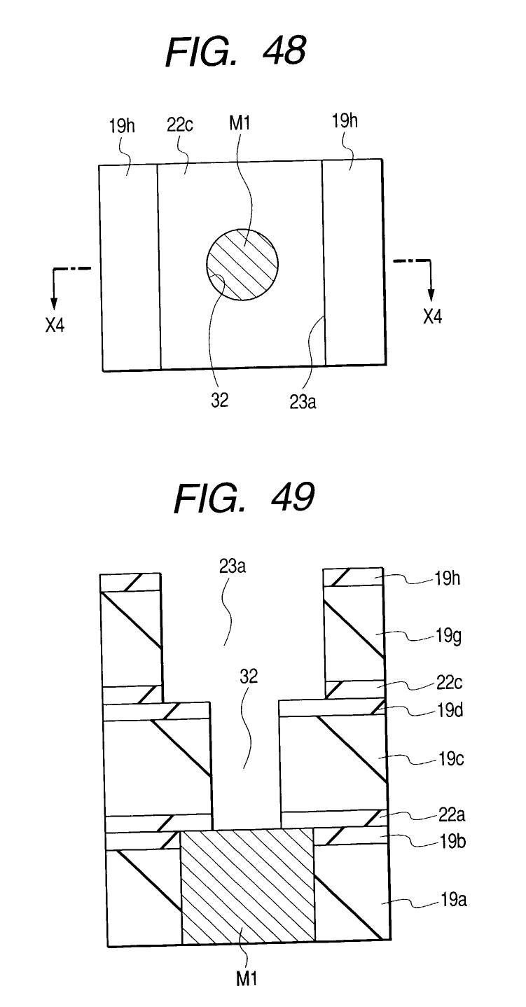

FIG. 48 is a fragmentary plain view of a semiconductor integrated circuit device during a fabrication method according to Embodiment 7; and FIG. 49 is a cross-sectional view taken along a line X4-X4 in FIG. 47. In each of insulating films 22c, 19g and 19h, an interconnect trench 23a is formed. The insulating film 22c is made, for example, of a silicon nitride film. The insulating films 19g,19h are made, for example, of a silicon oxide film. In the underlying insulating films 22a,19c,19d, a through-hole 32 is formed. This through-hole 32 is perforated so that the hole would extend from the bottom surface of the interconnect trench 23a to the upper surface of the first-level interconnect M1, in other words, the upper surface of the first-level interconnect M1 would be exposed from the bottom surface of the through-hole 32.

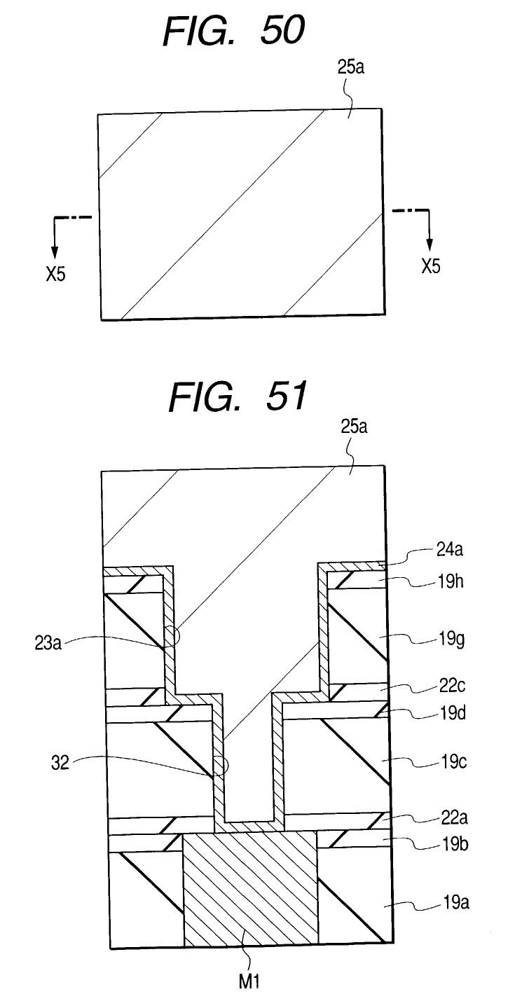

The subsequent step is shown in FIGS. 49 and 50. FIG. 50 is a cross-sectional view taken along a line X5-X5 in FIG. 49. Here, a conductive barrier film 24a made, for example, of tantalum (Ta) is deposited by sputtering under conditions similar to those described above. As the conductive barrier film, Ta is employed here, but TiN or another film exemplified above may be used.

Then, over the conductive barrier film 24a, a main conductor film 25a (seed film in this stage) made of copper is deposited by sputtering to a thickness of about 150 nm. Upon sputtering, oxygen free high conductivity copper having a high purity of, for example, 99.999% (5N) or greater, preferably 99.9999% (6N) or greater was used as a target. This makes it possible to increase the copper concentration in the main conductor film 25a upon its formation to 99.999% or greater, preferably 99.9999% or greater. Thus, high-purity copper can be deposited over the bottom surface and side surfaces of a copper interconnect.

A main conductor film 23a made of copper is then formed by electroplating, whereby the main conductor film 23a has gained its design thickness. Copper is embedded in the through-hole 32 by electroplating, for example, at a current density of about 0.5 to 1.0 A/dm² for about 40 seconds, while it is embedded in the interconnect trench 23a, for example, at a current density of 1.0 to 2.0 A/dm² for about 140 seconds. Then, hydrogen annealing is conducted as in the single damascene method. This annealing can be omitted if not necessary.

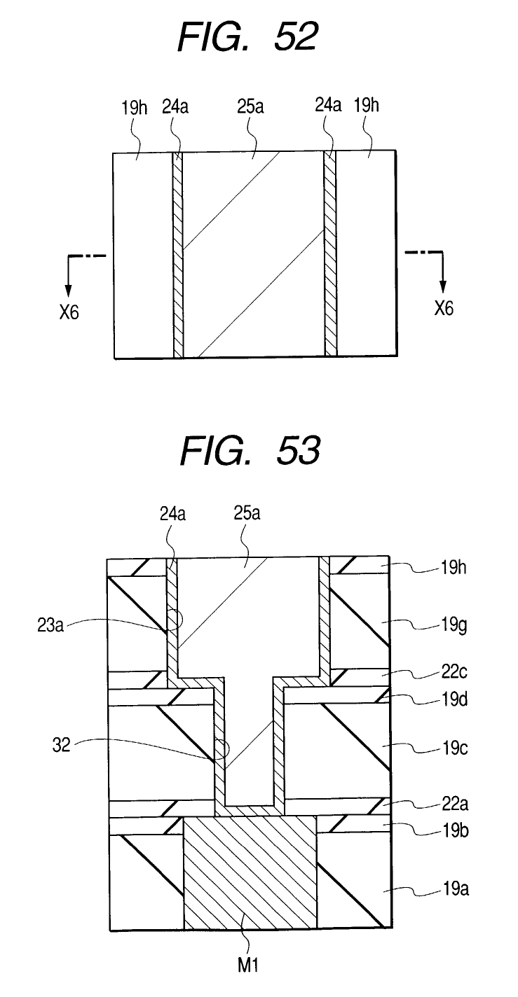

The subsequent step is shown in FIGS. 51 and 52. FIG. 52 is a cross-sectional view taken along a line X6-X6 in FIG. 51. After formation of an inlaid interconnect 26a by polishing of the main conductor film 23a and conductive barrier film 24a by CMP according to the above-described manner, thereby removing therefrom unnecessary portions, corrosion inhibition and post-CMP cleaning are conducted as described above. The inlaid interconnect 26a is electrically connected to the first-level interconnect M1 via a through-hole 32.

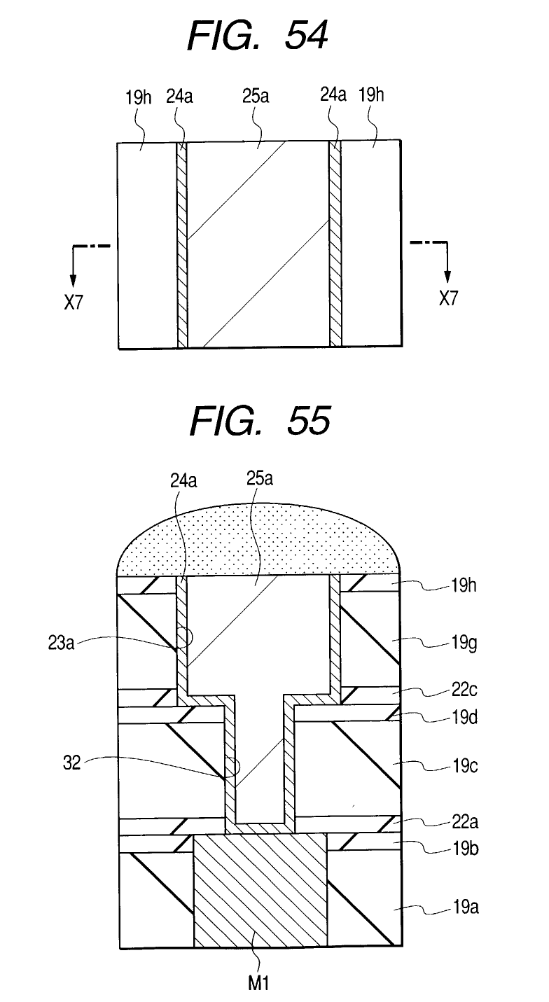

The subsequent step is shown in FIGS. 53 and 54. FIG. 54 is a cross-sectional view taken along a line X7-X7 in FIG. 53. In this step, the surfaces of the insulating film 19h and inlaid interconnect 26a are subjected to ammonia plasma treatment and hydrogen plasma treatment as described in Embodiments 1 to 6, which brings about similar effects to that obtained by the above-described dual damascene method.

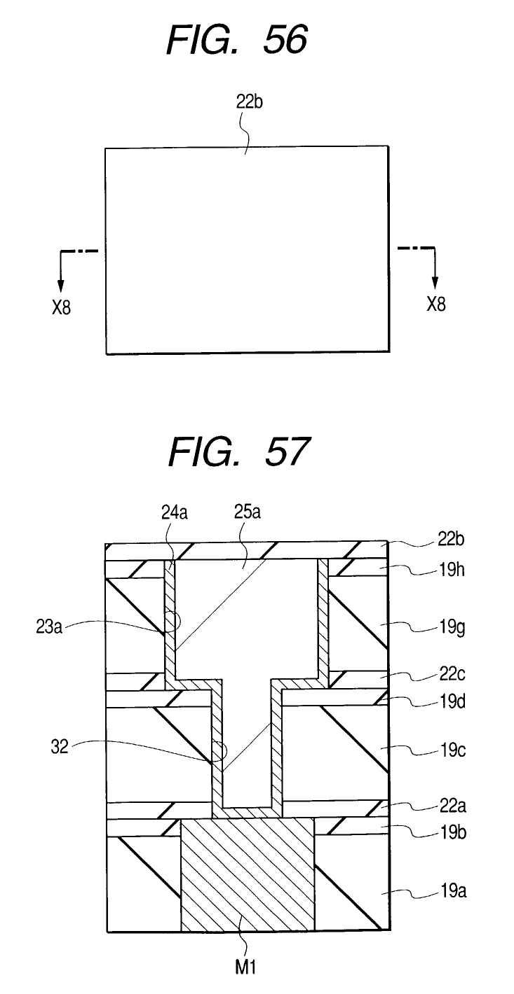

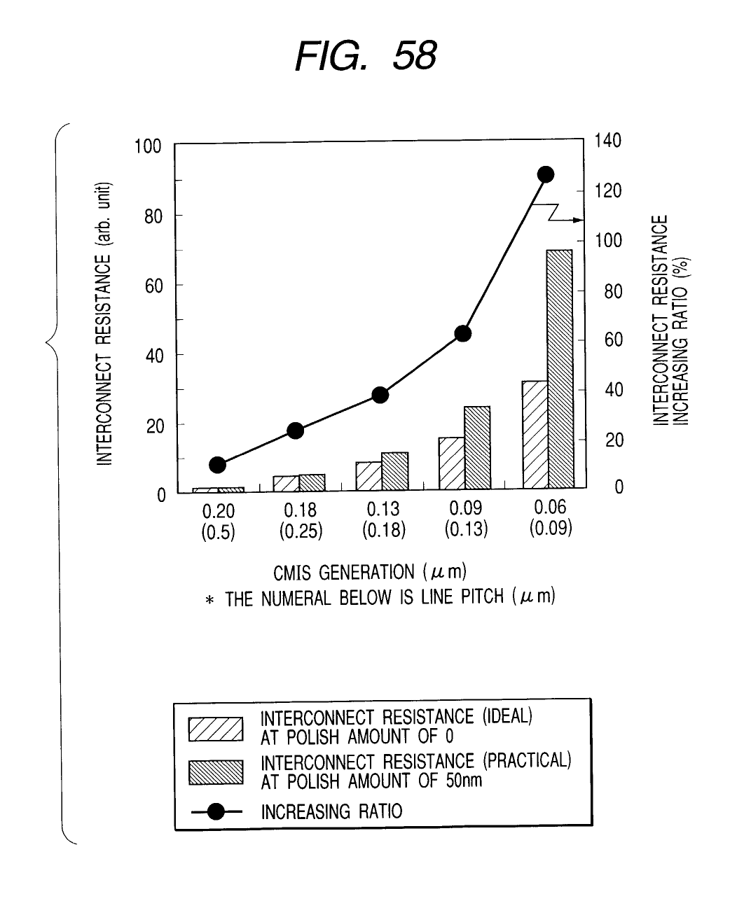

The subsequent step is illustrated in FIGS. 55 and 56. FIG. 56 is a cross-sectional view taken along a line X8-X8 in FIG. 55. In this step, an insulating film 22b is deposited as in Embodiment 1, whereby an interconnect structure by the dual damascene method is obtained.

In this Embodiment, in addition to the effect derived from the constitution peculiar to this Embodiment, effects similar to Embodiments 1 to 7 are also available for the constituting portions similar to those of Embodiments 1 to 7.

Although the invention made by the present inventors was concretely explained based on embodiments thereof, it is needless to say that the invention is not limited to the embodiments but may be modified in various ways within an extent not departing from the gist thereof.

In Embodiments 1 to 8, explanation was made on the case where at least two drying chambers are disposed in order to adjust timing between cleaning and drying. The present invention is not limited to it. It is also possible to reduce the number of drying chambers to one and instead, dispose a wafer waiting chamber between the cleaning chamber and drying chamber to adjust timing between cleaning and drying. In this case, the waiting chamber has a structure capable of keeping the wafer surface wet, for example, a structure capable of having the wafer waiting while dipping it in pure water, or while spraying it with pure water. This waiting chamber may be interposed between the first and second cleaning chambers or between the second cleaning chamber and the drying chamber. Alternatively, it is possible to allow the loader of the post-CMP cleaning apparatus to have a function as the waiting chamber, or the unloader of the CMP apparatus to have a function as the waiting chamber.

As another example for controlling timing between the cleaning and drying, the surface of the wafer is cleaned only with pure water in the cleaning chamber without bringing a brush into contact with the wafer.

Alternatively, it is possible to dispose a plurality of cleaning and drying chambers each having a mechanical part capable of carrying out both cleaning and drying treatments and, in each of these chambers, subject a wafer to cleaning and drying treatments.

In the above-described descriptions, the present invention made by the present inventors is applied to the fabrication method of a semiconductor integrated circuit device having a CMIS circuit as a background utilization field thereof. The invention is however not limited to it but can also be applied, for example, to the fabrication method of a semiconductor integrated circuit device having a memory circuit, such as a DRAM (dynamic random access memory), SRAM (static random access memory) or flash memory (EEPROM; electric erasable programmable read only memory), the fabrication method of a semiconductor integrated circuit device having a logic circuit such as microprocessor, or the fabrication method of a hybrid semiconductor integrated circuit device having a memory circuit and a logic circuit on the common semiconductor substrate. The invention is also applicable to a fabrication method of a device other than a semiconductor integrated circuit device, such as micro-machine or liquid-crystal substrate.

Of the inventions disclosed by the present application, effects available from the typical inventions are as follows:

A through-put of post-CMP cleaning can be improved by, upon post-CMP cleaning, cleaning wafers and then drying them in plural drying chambers in parallel.

What is claimed is:

1. A fabrication method of a semiconductor integrated circuit device, comprising the steps of:
(a) subjecting wafers to chemical mechanical polishing;
(b) cleaning the wafers in a cleaning chamber; and
(c) drying the wafers in two or more single-wafer drying chambers, which have been disposed downstream of the cleaning chamber, in parallel.

2. A fabrication method according to claim 1, wherein in said chemical mechanical polishing, abrasive-free polishing is followed by abrasive-used polishing.

3. A fabrication method according to claim 2, wherein said abrasive-free polishing is a step of polishing a main conductor film made of copper and said abrasive-used polishing is a step of polishing a conductive barrier film, and by said chemical mechanical polishing having said two steps, an inlaid interconnect is formed.

4. A fabrication method according to claim 1, wherein said cleaning step has a first cleaning step and a second cleaning step.

5. A fabrication method according to claim 4, wherein said first cleaning is alkali cleaning, while said second cleaning is acid cleaning.

6. A fabrication method according to claim 1, wherein said cleaning is shorter in time than said drying.

7. A fabrication method according to claim 1, wherein said cleaning comprises brush cleaning with a chemical solution and brush cleaning with pure water, and the brush cleaning with a chemical solution is shorter in time than said drying.

8. A fabrication method of a semiconductor integrated circuit device, comprising the steps of:
(a) subjecting wafers to chemical mechanical polishing;
(b) keeping said wafers wet and putting them on standby;
(c) cleaning said wafers in a cleaning chamber; and
(d) drying said wafers in two or more single-wafer drying chambers, which have been disposed downstream of the cleaning chamber, in parallel.

9. A fabrication method according to claim 8, wherein in said chemical mechanical polishing, abrasive-free polishing is followed by abrasive-used polishing.

10. A fabrication method according to claim 9, wherein said abrasive-free polishing is a step of polishing a main conductor film made of copper and said abrasive-used polishing is a step of polishing a conductive barrier film, and by said chemical mechanical polishing having said two steps, an inlaid interconnect is formed.

11. A fabrication method according to claim 8, wherein said step (b) is conducted while dipping said wafers in pure water or spraying said wafers with pure water.

12. A fabrication method according to claim 11, wherein said step (b) is conducted in a loader disposed upstream of said cleaning step.

13. A fabrication method according to claim 11, wherein said step (b) is conducted in an unloader disposed downstream of said chemical mechanical polishing step.

14. A fabrication method according to claim 11, wherein said cleaning step (c) has a first cleaning step and a second cleaning step and said step (b) is conducted between said first and second cleaning steps.

15. A fabrication method according to claim 8, wherein said cleaning step has a first cleaning step and a second cleaning step.

16. A fabrication method according to claim 15, wherein said first cleaning is alkali cleaning, while said second cleaning step is acid cleaning.

17. A fabrication method according to claim 8, wherein said cleaning is shorter in time than said drying.

18. A fabrication method according to claim 8, wherein said cleaning step comprises brush cleaning with a chemical solution and then, brush cleaning with pure water, and said brush cleaning with a chemical solution is shorter in time than said drying.

19. A fabrication method of a semiconductor integrated circuit device, comprising the steps of:
(a) subjecting wafers to chemical mechanical polishing;
(b) cleaning said wafers in a cleaning chamber;
(c) keeping said wafers wet and putting them on standby; and
(d) drying said wafers in a single-wafer drying chamber disposed downstream of said cleaning chamber.

20. A fabrication method according to claim 19, wherein in said chemical mechanical polishing, abrasive-free polishing is followed by abrasive-used polishing.

21. A fabrication method according to claim 20, wherein said abrasive-free polishing is a step of polishing a main conductor film made of copper and said abrasive-used polishing is a step of polishing a conductive barrier film, and by said chemical mechanical polishing having said two steps, an inlaid interconnect is formed.

22. A fabrication method according to claim 19, wherein said cleaning step has a first cleaning step and second cleaning step.

23. A fabrication method according to claim 22, wherein said first cleaning step is alkali cleaning, while said second cleaning step is acid cleaning.

24. A fabrication method according to claim 19, wherein said step (c) is conducted while dipping said wafers in pure water or spraying said wafers with pure water.

25. A fabrication method according to claim 24, wherein said step (c) is carried out in a loader disposed upstream of said cleaning step.

26. A fabrication method according to claim 24, wherein said step (c) is carried out in an unloader disposed downstream of said chemical mechanical polishing step.

27. A fabrication method according to claim 24, wherein said cleaning step (b) has a first cleaning step and a second cleaning step, and said step (c) is conducted therebetween.

28. A fabrication method according to claim 19, wherein said step (c) is conducted in said cleaning chamber not by mechanical cleaning said wafers with a brush but by cleaning with water.

29. A fabrication method of a semiconductor integrated circuit device, comprising the steps of:
(a) subjecting wafers to chemical mechanical polishing;
(b) cleaning said wafers; and
(c) drying said wafers, wherein said cleaning and drying steps are conducted successively in one same single-wafer cleaning and drying chamber and the number of said single-wafer cleaning and drying chamber disposed is two or more.

30. A fabrication method of a semiconductor integrated circuit device, comprising the steps of:
(a) subjecting wafers to chemical mechanical polishing;
(b) keeping said wafers wet and putting them on standby;
(c) cleaning said wafers; and
(c) drying said wafers,
wherein said cleaning and drying steps are conducted successively in one same single-wafer cleaning and drying chamber and the number of said single-wafer cleaning and drying chamber disposed is two or more.

31. A fabrication method of a semiconductor integrated circuit device, comprising the steps of:
(a) depositing an insulating film on the main surface of each of wafers;
(b) forming an interconnection opening in said insulating film;
(c) depositing over said insulating film a conductor film to embed therewith said interconnection opening;
(d) subjecting said wafers to chemical mechanical polishing, thereby forming an inlaid interconnect made of said conductor film in said interconnection opening;
(e) keeping said wafers wet and putting them on standby;
(f) cleaning said wafers in a cleaning chamber; and
(g) drying said wafers in each of two or more single-wafer drying chambers, which have been disposed downstream of said cleaning chamber, in parallel.

32. A fabrication method according to claim 31, wherein said step (c) comprises depositing a conductive barrier film and depositing thereover a main conductor film made of copper, thereby forming said conductor film.

33. A fabrication method according to claim 32, wherein said step (d) comprises carrying out abrasive-free polishing mainly for polishing said main conductor film made of copper and carrying out abrasive-used polishing mainly for polishing said conductive barrier film.

34. A fabrication method according to claim 31, wherein said step (e) is conducted while dipping said wafers in pure water or spraying them with pure water.

35. A fabrication method according to claim 31, wherein said cleaning step further comprises a first cleaning step and a second cleaning step.

36. A fabrication method according to claim 35, wherein said first cleaning step is alkali cleaning, while said second cleaning step is acid cleaning.

37. A fabrication method according to claim 31, wherein said cleaning is shorter in time than said drying.

38. A fabrication method according to claim 31, wherein said cleaning step further comprises brush cleaning with a chemical solution and then brush cleaning with pure water, said brush cleaning with a chemical solution being shorter in time than said drying.
